(19) United States
(12) Patent Application Publication
(10) Pub. No.: US 2024/0357839 A1
(43) Pub. Date: Oct. 24, 2024

(54) MEMORY STACKS INCLUDING REPLACEMENT BLOCKS AND RELATED METHODS

(71) Applicants: Nitin Ashok Deshpande, Chandler, AZ (US); Omkar Gopalkrishna Karhade, Chandler, AZ (US); Debendra Mallik, Chandler, AZ (US)

(72) Inventors: Nitin Ashok Deshpande, Chandler, AZ (US); Omkar Gopalkrishna Karhade, Chandler, AZ (US); Debendra Mallik, Chandler, AZ (US)

(21) Appl. No.: 18/759,039

(22) Filed: Jun. 28, 2024

(51) Int. Cl. H10B 80/00; H01L 23/00; H01L 25/00; H01L 25/065

(52) U.S. Cl. CPC H10B 80/00; H01L 24/08; H01L 24/80; H01L 24/94; H01L 25/0657; H01L 25/50; H01L 2224/08145; H01L 2224/80006; H01L 2224/80895; H01L 2224/80896; H01L 2224/80908

(57) ABSTRACT

Memory stacks including replacement blocks and related methods are disclosed. An example integrated circuit disclosed herein includes a first layer including a memory die, and a second layer including a replacement block communicatively coupled to the memory die, the second layer including and a dielectric shell surrounding the replacement block.

### BACKGROUND

In many electronic devices, integrated circuit (IC) chips and/or semiconductor dies are connected to larger circuit boards such as motherboards and/or other types of printed circuit boards (PCBs) via a package substrate. IC chips can be coupled to a variety of components via traces extending through printed circuit boards.

### BRIEF DESCRIPTION OF THE DRAWINGS

FIG. 1 is a cross-sectional side view of an example integrated circuit (IC) package including a memory stack in which teachings of this disclosure can be implemented.

FIG. 2 is a cross-sectional side view of an example memory stack that can implement the memory stack of FIG. 1.

FIGS. 3-14 are cross-sectional views depicting the memory stack of FIG. 2 in various intermediate stages of manufacture.

FIG. 15 is a cross-sectional side view of another example memory stack that can implement the memory stack of FIG. 1.

FIGS. 16 and 17 are cross-sectional views depicting the memory stack of FIG. 15 in intermediate stages of manufacture.

FIG. 18 is a cross-sectional side view of another example memory stack that can implement the memory stack of FIG. 1.

FIGS. 19 and 20 are cross-sectional views depicting the memory stack of FIG. 18 in various intermediate stages of manufacture.

FIG. 21 is a flowchart representative of an example manufacturing process for manufacturing the memory stacks of FIGS. 2, 15, and 18.

FIG. 22 is a top view of a wafer and dies that may be included in an IC package constructed in accordance with teachings disclosed herein.

FIG. 23 is a cross-sectional side view of an IC device that may be included in an IC package constructed in accordance with teachings disclosed herein.

FIG. 24 is a cross-sectional side view of an IC device assembly that may include an IC package constructed in accordance with teachings disclosed herein.

FIG. 25 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

In recent years, the stacking of memory, such as high bandwidth memory (HBM) stacks, has been developed to increase the memory density of integrated circuit packages. Memory stacks are circuitry modules that include a plurality of memory dies that are vertically stacking, which enables additional memory dies to be packaged in an integrated circuit package without increasing the planar area of the integrated circuit package. As the processing and storage demands of devices have increased, the need for larger and taller memory stacks has similarly increased. Some prior memory stacks include a plurality of memory dies arranged in sequence. In some such memory stacks, a non-functional memory die in the memory stack can render the entire memory stack non-functional. That is, because of the sequential arrangement of memory dies in a memory stack, a single non-functional memory die in the memory stack can render the entire memory stack non-functional. As such, for a memory stack of eight memory dies, even a relatively high yield rate of functional memory dies (e.g., 90%) can cause relatively low yield rates of functional memory stacks (e.g., 43%).

Examples disclosed herein include memory stacks with replacement blocks that mitigate one or more of the above-noted deficiencies. Examples disclosed herein include memory stacks with replacement blocks that replace non-functional dies during fabrication of the memory stacks. Some memory stacks disclosed herein include replacement memory dies, which are replacement blocks that include known good memory dies. Some memory stacks disclosed herein include replacement dummy dies, which are replacement blocks that include passthrough silicon dies. Some memory stacks disclosed herein include dielectric filler blocks, which are replacement blocks that are solid dielectric material. Examples disclosed herein improve the yield rate of memory stacks and enable the fabrication of memory stacks with a large number of layers (e.g., eight or more layers, etc.).

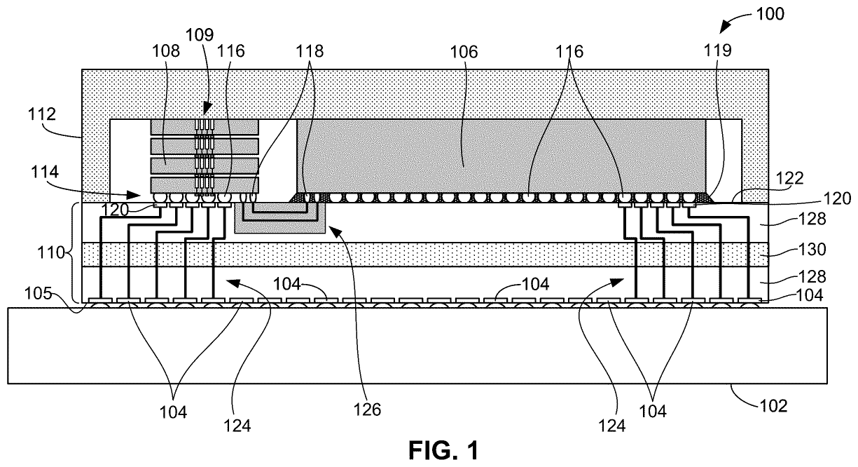

FIG. 1 illustrates an example integrated circuit (IC) package 100 constructed in accordance with teachings disclosed herein. In the illustrated example, the IC package 100 is electrically coupled to a circuit board 102 via an array of contact pads 104 (e.g., lands, etc.) on a mounting surface 105 (e.g., a bottom surface) of the package. In some examples, the IC package 100 may include balls, pins, and/or pads, in addition to or instead of the contact pads 104, to enable the electrical coupling of the IC package 100 to the circuit board 102. In this example, the IC package 100 includes a die 106 (e.g., a silicon die, a semiconductor die, etc.) and an example memory stack 108 that is mounted to a package substrate 110 and enclosed by a package lid 112 (e.g., a mold compound, etc.). Thus, the package substrate 110 is an example means for supporting a semiconductor die. While the example IC package 100 of FIG. 1 includes the die 106 and the memory stack 108, in other examples, the IC package 100 may include additional dies. In some examples, some or all of the die 106, the memory stack 108, or a separate die are embedded in the package substrate 110. The die 106 can provide any suitable type of functionality (e.g., data processing, memory storage, etc.).

The memory stack 108 is a memory module that includes a stack of multiple memory dies. In some examples, the memory stack 108 is a high bandwidth memory (HBM) stack. In some examples, the memory stack 108 is implemented in accordance with a High-Bandwidth Interface (HBI) standard. Additionally or alternatively, the memory stack 108 can be implemented in accordance with a different memory stacking standard. In the illustrated example of FIG. 1, the memory stack 108 includes four layers of stacked memory dies. In other examples, the memory stack 108 can include a different number of stack memory dies (e.g., eight layers, nine layers, sixteen layers, etc.).

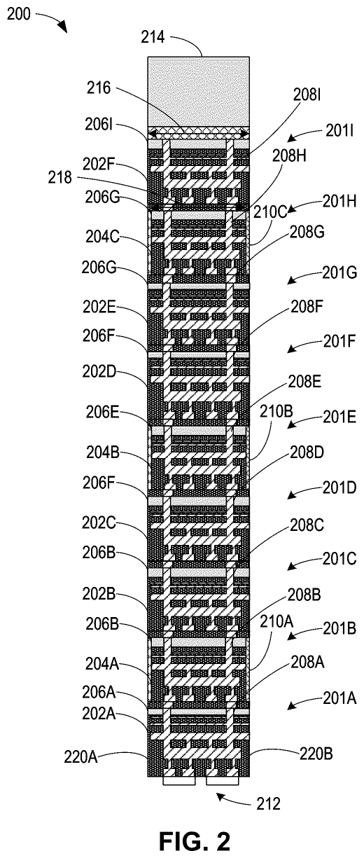

In the illustrated example of FIG. 1, the vertically adjacent ones of the memory dies of the memory stack 108 are connected via vias 109, which enables electrical communication between adjacent dies of the memory stack 108. In some examples, some or all of the memory dies of the memory stack 108 are dynamic random access memory (DRAM) dies. Additionally or alternatively, the memory stack 108 can include different memory dies. In the illustrated example of FIG. 1, each of the layers of the memory stack 108 can include a single memory die ea. In other examples, each layer of the memory stack 108 can include multiple memory dies. Example memory stacks implemented in accordance with teachings of this disclosure are described below in conjunction with FIGS. 2-21.

In the illustrated example of FIG. 1, the die 106 and the memory stack 108 are electrically and mechanically coupled to the package substrate 110 via corresponding arrays of interconnects 114. In the illustrated example of FIG. 1, the interconnects 114 are bumps. In other examples, the interconnects 114 can be implemented any other type of electrical connection in addition to or instead of the bumps shown (e.g., balls, pins, pads, wire bonding, etc.). The electrical connections between the die 106 and the memory stack 108 and the package substrate 110 (e.g., the interconnects 114, etc.) are referred to herein as “first level interconnects.” The electrical connections between the IC package 100 and the circuit board 102 (e.g., the contact pads 104, etc.) are referred to herein as “second level interconnects.” In some examples, one or both the die 106 and the memory stack 108 are stacked on top of one or more other dies and/or an interposer. In some such examples, the die 106 and the memory stack 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

In the illustrated example of FIG. 1, the interconnects 114 of the first level interconnects include two different types of bumps corresponding to core bumps 116 and bridge bumps 118. As used herein, the core bumps 116 are bumps on the die 106 and the memory stack 108 through which electrical signals pass between the die 106 and the memory stack 108 and components external to the IC package 100. That is, as shown in the illustrated example, when the die 106 and the memory stack 108 are mounted to the package substrate 110, the core bumps 116 are physically connected and electrically coupled to contact pads 120 on an inner surface 122 of the package substrate 110. The contact pads 120 on the inner surface 122 of the package substrate 110 are electrically coupled to the contact pads 104 on the mounting surface 105 of the package substrate 110 (e.g., a surface opposite the inner surface 122, an external bottom surface, etc.) via internal interconnects 124 within the package substrate 110. As a result, there is a continuous electrical signal path between the interconnects 114 and the contacts pads 104 mounted to the circuit board 102 that pass through the contact pads 120 and the internal interconnects 124 provided therebetween.

As used herein, the bridge bumps 118 are bumps on the die 106 and the memory stack 108 through which electrical signals pass between different ones of the die 106 and the memory stack 108 within the IC package 100. Thus, as shown in the illustrated example, the bridge bumps 118 of the die 106 are electrically coupled to the bridge bumps 118 of the memory stack 108 via an interconnect bridge 126 embedded in the package substrate 110. As represented in FIG. 1, core bumps 116 are typically larger than bridge bumps 118. In some examples, the interconnect bridge 126 and the associated bridge bumps 118 are omitted.

For purposes of illustration, the internal interconnects 124 are shown as straight lines extending directly between the contact pads 104 on the mounting surface 105 and the contact pads on the inner surface 122. However, in some examples, the internal interconnects 124 are defined by traces or routing in separate conductive (e.g., metal) layers within build-up regions 128 on one or both sides of a substrate core 130 in the package substrate 110. In such examples, the build-up regions 128 include dielectric layers to separate the different conductive layers. In such examples, the traces or routing in the different conductive layers are electrically coupled (to define the complete electrical path of the internal interconnects 124) by conductive (e.g., metal) vias extending between the different conductive layers. Further, in some examples, the internal interconnects 124 include vias that extend through the substrate core 130.

FIG. 2 is a cross-sectional side view of an example first memory stack 200 that can implement the memory stack 108 of FIG. 1. In the illustrated example of FIG. 2, the first memory stack 200 includes an example first layer 201A, an example second layer 201B, an example third layer 201C, an example fourth layer 201D, an example fifth layer 201E, an example sixth layer 201F, an example seventh layer 201G, an example eighth layer 201H, and an example ninth layer 201I. As used herein, the layers 201A, 201B, 201C, 201D, 201E, 201F, 201G, 201H, 201I are also referred to herein as “memory layers.” In the illustrated example of FIG. 2, the first memory stack 200 includes an example first memory die 202A, an example second memory die 202B, an example third memory die 202C, an example fourth memory die 202D, an example fifth memory die 202E, and an example sixth memory die 202F. In the illustrated example of FIG. 2, the first memory stack 200 further includes an example first replacement die 204A, an example second replacement die 204B, and an example third replacement die 204C. In the illustrated example of FIG. 2, the layers 201A, 201B, 201C, 201D, 201E, 201F, 201G, 201H, 201I include an example first base 206A, an example second base 206B, an example third base 206C, an example fourth base 206D, an example fifth base 206E, an example sixth base 206F, an example seventh base 206G, an example eighth base 206H, and an example ninth base 206I, respectively.

In the illustrated example of FIG. 2, the first memory die 202A includes an example first interconnection 208A, the first replacement die 204A includes an example second interconnection 208B, the second memory die 202B includes an example third interconnection 208C, the third memory die 202C includes an example fourth interconnection 208D, the second replacement die 204B includes an example fifth interconnection 208E, the fourth memory die 202D includes an example sixth interconnection 208F, the third replacement die 204C includes an example seventh interconnection 208G, the fifth memory die 202E includes an example eighth interconnection 208H, and the sixth memory die 202F includes an example ninth interconnection 208I. In the illustrated example of FIG. 2, the replacement dies 204A, 204B, 204C include an example first dielectric shell 210A, an example second dielectric shell 210B, and an example third dielectric shell 210C, respectively. In the illustrated example of FIG. 2, the first memory stack 200 includes example pads 212 and an example structural lid 214.

The memory dies 202A, 202B, 202C, 202D, 202E, 202F are semiconductor dies that function as memory for an integrated circuit package including the first memory stack 200 (e.g., the integrated circuit package 100, etc.). In some examples, some or all of the memory dies 202A, 202B, 202C, 202D, 202E, 202F are implemented by a dynamic random-access memory (DRAM) (e.g., synchronous DRAM, video DRAM, extreme data rate DRAM, synchronous graphics RAM, etc.). In other examples, the memory dies 202A, 202B, 202C, 202D, 202E, 202F are implemented by another suitable type of memory unit (e.g., another type of volatile memory, a non-volatile memory unit, etc.). In the illustrated example of FIG. 2, the memory dies 202A, 202B, 202C, 202D, 202E, 202F have an example first width 216. In the illustrated example of FIG. 2, the first memory stack 200 has the first width 216. That is, in the illustrated example of FIG. 2, the memory dies 202A, 202B, 202C, 202D, 202E, 202F extend along the entire width of the first memory stack 200.

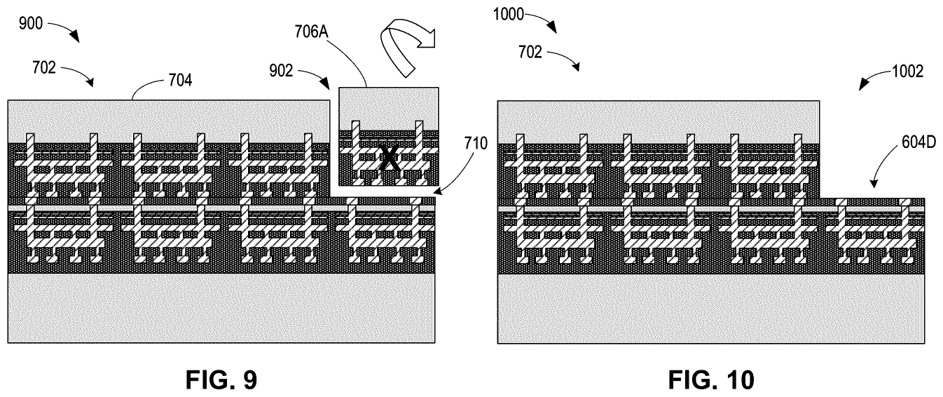

The replacement dies 204A, 204B, 204C are memory dies that are similar to the memory dies 202A, 202B, 202C, 202D, 202E, 202F. In some examples, the replacement dies 204A, 204B, 204C are implemented by a same type of memory unit as the memory dies 202A, 202B, 202C, 202D, 202E, 202F. In other examples, the replacement dies 204A, 204B, 204C are a different type of memory unit as some or all of the memory dies 202A, 202B, 202C, 202D, 202E, 202F. As used herein, the replacement dies 204A, 204B, 204C are also referred to as “known good dies (KGD).” During the fabrication of the first memory stack 200, other memory dies initially disposed in the first memory stack 200 can be identified as non-functional (e.g., faulty, defective, etc.). In some such examples, the identified non-functional dies can be removed and replaced by the replacement dies 204A, 204B, 204C in the first memory stack 200. In some examples, the dielectric shells 210A, 210B, 210C can be disposed around the 204A, 204B, 204C to facilitate the incorporation of the replacement dies 204A, 204B, 204C in the memory stack 200. The deposition of replacement dies is described in additional detail below in conjunction with FIGS. 9-12 and 21.

In the illustrated example of FIG. 2, the replacement dies 204A, 204B, 204C have an example second width 218. In the illustrated example of FIG. 2, the second width 218 is less than the first width 216. For example, each corresponding set of the replacement dies 204A, 204B, 204C and the dielectric shells 210A, 210B, 210C (e.g., the first replacement die 204A and the first dielectric shell 210A, the second replacement die 204B and the second dielectric shell 210B, etc.) have a combined width approximately equal to the first width 216.

The bases 206A, 206B, 206C, 206D, 206E, 206F, 206G, 206H, 206I are structural layers that support the dies 202A, 204A, 202B, 202C, 204B, 202D, 202E, 204C, 202F, respectively. The bases 206A, 206B, 206C, 206D, 206E, 206F, 206G, 206H, 206I are also referred to herein interchangeably as “base layers,” “silicon layers,” “structural layers,” and “silicon bases.” In some examples, the bases 206A, 206B, 206C, 206D, 206E, 206F, 206G, 206H, 206I include (e.g., are composed of, etc.) silicon. In other examples, the 206A, 206B, 206C, 206D, 206E, 206F, 206G, 206H, 206I can be composed of any other suitable material. In some examples, the bases 206A, 206B, 206C, 206D, 206E, 206F, 206G, 206H, 206I are residual components of the wafers on which the dies 202A, 204A, 202B, 202C, 204B, 202D, 202E, 204C, 202F, respectively, were fabricated.

The interconnections 208A, 208B, 208C, 208D, 208E, 208F, 208G, 208H, 208I are electrical conductive structures that transmit electrical signals and power between the layers 201A, 201B, 201C, 201D, 201E, 201F, 201G, 201H, 201I. For example, the first interconnections 208A are in the first layer 201A and the first memory die 202A, the second interconnections 208B are in the second layer 201B and the first replacement die 204A, etc. The interconnections 208A, 208B, 208C, 208D, 208E, 208F, 208G, 208H, 208I can include vias, traces, pads, balls, etc. that electrical transmit signals and/or power through the memory dies 202A, 202B, 202C, 202D, 202E, 202F and the replacement dies 204A, 204B, 204C. In some examples, the interconnections 208A, 208B, 208C, 208D, 208E, 208F, 208G, 208H, 208I include (e.g., are composed of, etc.) an electrically conductive material, such as copper, aluminum, iron, etc. In the illustrated example of FIG. 2, the interconnections 208A, 208B, 208C, 208D, 208E, 208F, 208G, 208H, 208I extend through the bases 206A, 206B, 206C, 206D, 206E, 206F, 206G, 206H, 206I, respectively.

The dielectric shells 210A, 210B, 210C surround (e.g., encompass, etc.) the sides of the replacement dies 204A, 204B, 204C, respectively. The dielectric shells 210A, 210B, 210C include (e.g., are composed of, etc.) a dielectric material (e.g., an epoxy, silica, a plastic, a ceramic, a metal oxide, etc. In other examples, the dielectric shells 210A, 210B, 210C can be composed of a different type of material.

The pads 212 are contact pads that enable the first memory stack 200 to be coupled to a package substrate of an integrated circuit package. For example, the pads 212 can be coupled to the contact pads 120 of FIG. 1 via a ball grid array (BGA) and/or the core bumps 116 of FIG. 1. In other examples, the pads 212 can be coupled to the package substrate 110 of FIG. 1 of the integrated circuit package 100 of FIG. 1. In other examples, the first memory stack 200 is coupled to a package substrate via another type of surface mounting (e.g., a land grid array (LGA), etc.). In the illustrated example of FIG. 2, the pads 212 are disposed on the bottom surface of the bottom layer of the first memory stack 200 (e.g., the bottom of the first memory die 202A, the bottom surface of the first layer 201A, etc.). In the illustrated example of FIG. 2, the pads 212 are electrically coupled to the interconnects 208I, which enables electrical signals to be transmitted through the memory dies 202A, 202B, 202C, 202D, 202E, 202F and the replacement dies 204A, 204B, 204C. In the illustrated example of FIG. 2, the first memory stack 200 includes two pads (e.g., the pads 212, etc.). In other examples, the first memory stack 200 can include a different quantity of pads (e.g., one pad, five pads, fifty pads, one hundred pads, one thousand pads, etc.).

The structural lid 214 is disposed on the uppermost layer of the first memory stack 200 (e.g., the ninth layer 201I, etc.). In some examples, the structural lid 214 abuts and/or is adjacent to the package lid 112 of the integrated circuit package 100. That is, the structural lid 214 is above each of the layers 201A, 201B, 201C, 201D, 201E, 201F, 201G, 201H, 201I. In some examples, the structural lid 214 has the first width 216 (e.g., the same width as the memory dies 202A, 202B, 202C, 202D, 202E, 202F, the combined width of the replacement dies 204A, 204B, 204C and the dielectric shells 210A, 210B, 210C, etc.). In other examples, the structural lid 214 has a different width (e.g., the second width 218, a width greater than the first width 216, etc.). In some examples, the thickness of the structural lid 214 can be determined based on the overall mechanical and/or thermal properties of the first memory stack 200. For example, the thickness of the structural lid 214 can be selected such that the first memory stack 200 has a desired mechanical stiffness, a desired thermal expansion coefficient, a desired mechanical strength, etc. In some such examples, the thickness of the structural lid 214 is based on the quantity of replacement dies 204A, 204B, 204C because of the different mechanical and/or thermal properties of the replacement dies 204A, 204B, 204C and the memory dies 202A, 202B, 202C, 202D, 202E, 202F. In some examples, the structural lid 214 includes (e.g., is composed of, etc.) silicon, etc. Additionally or alternatively, the structural lid 214 can be composed of a different material. In some examples, the structural lid 214 is absent. In some such examples, the uppermost layer of the first memory stack 200 (e.g., the ninth layer 201I, etc.) abuts and/or is adjacent to the package lid 112 of FIG. 1 of the integrated circuit package 100 of FIG. 1.

In the illustrated example of FIG. 2, the first memory stack 200 includes an example first edge 220A and an example second edge 220B. In the illustrated example of FIG. 2, the edges 220A, 220B are defined by the memory dies 202A, 202B, 202C, 202D, 202E, 202F and the dielectric shells 210A, 210B, 210C. In the illustrated example of FIG. 2, the memory dies 202A, 202B, 202C, 202D, 202E, 202F and the dielectric shells 210A, 210B, 210C are substantially flush at the edges 220A, 220B. In the illustrated example of FIG. 2, the base layers associated with the layers that include the memory dies 202A, 202B, 202C, 202D, 202E, 202F (e.g., the base 206A, 206C, 206D, 206F, 206G, 206I associated with the layers 201A, 201C, 201D, 201F, 201G, 201I, etc.) extend to the edges 220A, 220B. In the illustrated example of FIG. 2, the base layers associated with the layers that include the replacement dies 204A, 204B, 204C (e.g., the bases 206B, 206E, 206H associated with the layers 201B, 201E, 201H, etc.) do not extend to the edges 220A, 220B. That is, the bases 206B, 206E, 206H are enclosed (e.g., surrounded, etc.) by the dielectric shells 210A, 210B, 210C.

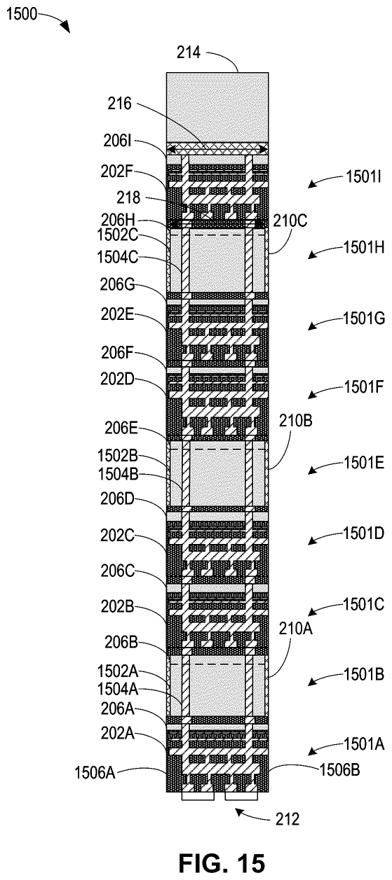

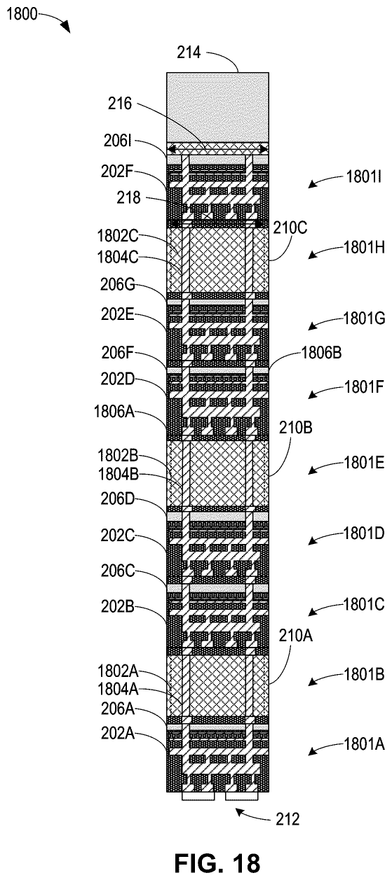

In the illustrated example of FIG. 2, the first memory stack 200 includes nine layers (e.g., the layers 201A, 201B, 201C, 201D, 201E, 201F, 201G, 201H, 201I, etc.) and nine memory dies (e.g., the memory dies 202A, 202B, 202C, 202D, 202E, 202F and the replacement dies 204A, 204B, 204C, etc.). In other examples, the first memory stack 200 includes a different quantity of layers and/or different quantity of memory dies (e.g., four memory dies, eight memory dies, ten memory dies, sixteen memory dies, seventeen memory dies, etc.). Example memory stacks including unequal quantities of layers and memory dies are described below in conjunction with FIGS. 15 and 18.

In the illustrated example of FIG. 2, the memory dies 202A, 202B, 202C, 202D, 202E, 202F and the replacement dies 204A, 204B, 204C are disposed in sequence. That is, the electrical signals are transmitted sequentially through the interconnections 208A, 208B, 208C, 208D, 208E, 208F, 208G, 208H, 208I of the memory dies 202A, 202B, 202C, 202D, 202E, 202F and the replacement dies 204A, 204B, 204C. For example, electrical signals transmitted to the second memory die 202B are transmitted sequentially through the pads 212, through the first interconnections 208A of the first memory die 202A, and then through the second interconnections 208B of the first replacement die 204A. It should be appreciated that, because the sequential coupling of memory dies in the first memory stack 200, the presence of non-functional die in the first memory stack 200 can prevent the transmission of signals to the other dies of the first memory stack 200. For example, if the first memory die 202A is non-functional, signals cannot be transmitted to the dies above the first memory die 202A (e.g., the memory dies 202B, 202C, 202D, 202E, 202F and the replacement dies 204A, 204B, 204C, etc.). Accordingly, the presence of non-functional dies in the first memory stack 200 can reduce the functionality of the first memory stack 200 (e.g., render the first memory stack 200 fully non-functional, render the memory stack partially non-functional, etc.). The usage of the replacement dies 204A, 204B, 204C in the first memory stack 200 and the associated method of fabrication disclosed below mitigates (e.g., prevents, reduces, etc.) the likelihood of non-functional dies rendering the first memory stack 200 non-functional.

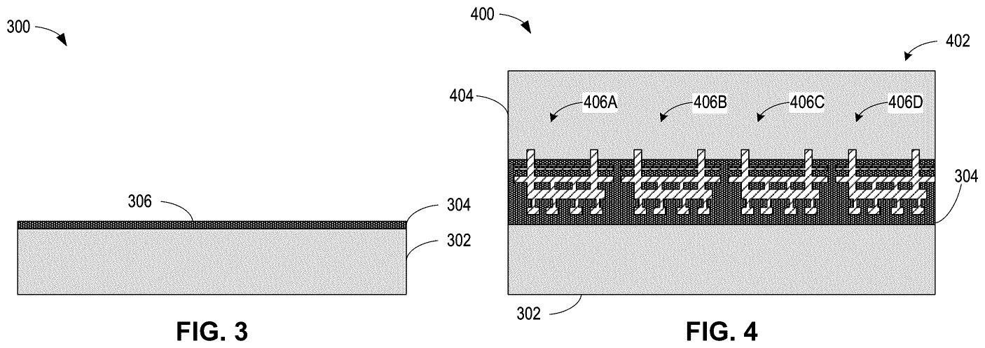

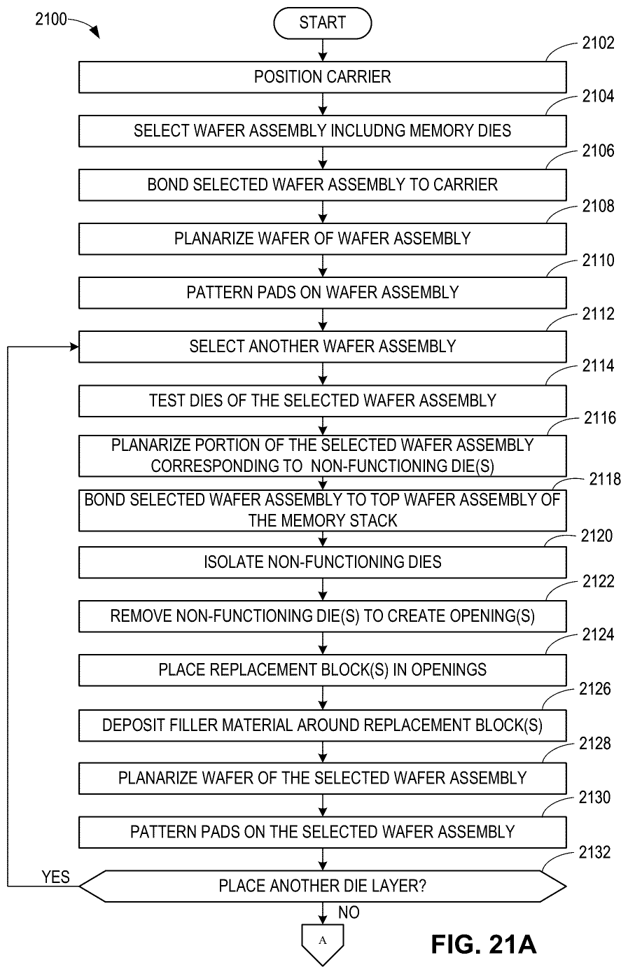

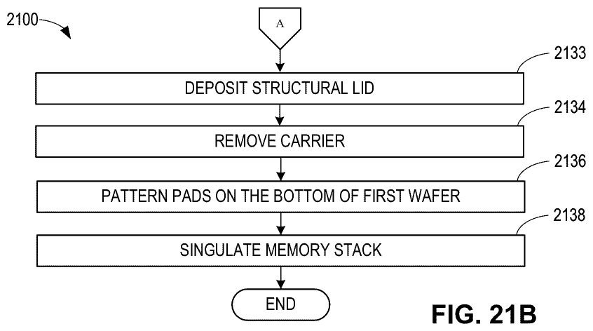

FIGS. 3-14 depict a plurality of intermediate stages in an example process to manufacture the first memory stack 200 of FIG. 2. In the illustrated examples of FIGS. 3-14, the intermediate stages depict wafer-level fabrication to manufacture a row of four memory stacks similar to the first memory stack 200. It should be appreciated that the examples disclosed herein can be used to manufacture any suitable quantity of memory stacks simultaneously (e.g., based on the sized of the wafer on which the memory stacks are assembled on, etc.). It should be appreciated that other processes and/or intermediate stages can be used to manufacture the first memory stack 200 of FIG. 2. Example operations to manufacture the first memory stack 200 of FIG. 2 via the intermediate stages of FIGS. 3-14 are described below in conjunction with FIG. 21.

FIG. 3 is a cross-sectional schematic view of an example first intermediate stage 300 of the assembly/manufacturing of the first memory stack 200 of FIG. 2. During the first intermediate stage 300, an example carrier 302 is provided. For example, a carrier 302 can be positioned onto and/or within a die fabrication system. The carrier 302 is a rigid component that supports the dies and/or other components of the memory stack(s) to be manufactured via the intermediate stages of FIGS. 3-14. The carrier 302 can include (e.g., is composed of, etc.) any rigid suitable material (e.g., epoxy-based prepreg, glass, silicon, germanium, selenium, tellurium, etc.). In the illustrated example of FIG. 3, the carrier 302 includes an example first bonding layer 304. The first bonding layer 304 facilitates the bonding of another wafer and/or other components to be bonded to an example top surface 306 of the carrier 302. In some examples, the first bonding layer 304 is a fusion bonding layer. In other examples, the first bonding layer 304 includes silica. In other examples, the first bonding layer 304 can include any other suitable material. In some examples, the first bonding layer 304 is planarized (e.g., via chemical mechanical polishing, etc.)

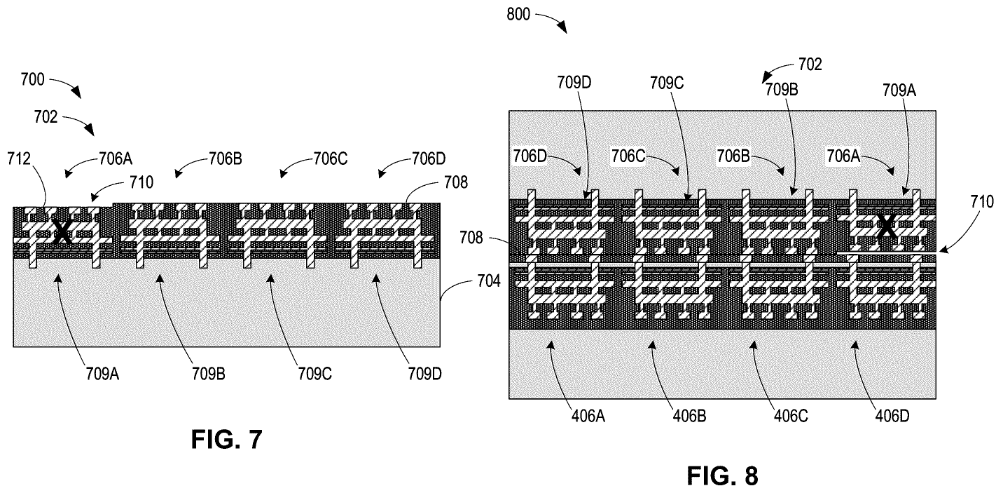

FIG. 4 is a cross-sectional schematic view of an example second intermediate stage 400 of the assembly/manufacturing of the first memory stack 200 of FIG. 2. In some examples, the second intermediate stage 400 occurs after the first intermediate stage 300 of FIG. 3. During the second intermediate stage 400, an example wafer assembly 402 has been bonded to the top surface 306 of FIG. 3. As used herein, the term “wafer assembly” refers to a non-singulated wafer that includes a plurality memory dies fabricated thereon. In the illustrated example of FIG. 4, the first wafer assembly 402 includes an example wafer 404, an example first memory die 406A, an example second memory die 406B, an example third memory die 406C, and an example fourth memory die 406D. In the illustrated example of FIG. 4, the memory dies 406A, 406B, 406C, 406D are similar to the memory dies 202A, 202B, 202C, 202D, 202E, 202F of FIG. 2. In some examples, the first wafer assembly 402 is fusion bonded to the carrier 302 via the first bonding layer 304 of FIG. 3. In other examples, the first wafer assembly 402 can be bonded to the carrier 302 via another wafer bonding technique (e.g., surface activated bonding, plasma activated bonding, anodic bonding, eutectic bonding, etc.). In some examples, the memory dies 406A, 406B, 406C, 406D are tested to verify the memory dies 406A, 406B, 406C, 406D are functional prior to the deposition of the first wafer assembly 402. In some such examples, the first wafer assembly 402 is discarded if one or more of the memory dies 406A, 406B, 406C, 406D. In some such examples, the functional one(s) of the memory dies 406A, 406B, 406C, 406D are extracted and can be used a replacement dies. In other examples, the non-functional one(s) of the memory dies 406A, 406B, 406C, 406D can be removed and replaced in manner similar to the process described in conjunction with FIGS. 7-12. In other examples, the memory dies 406A, 406B, 406C, 406D are tested later in the fabrication process of the first memory stack 200.

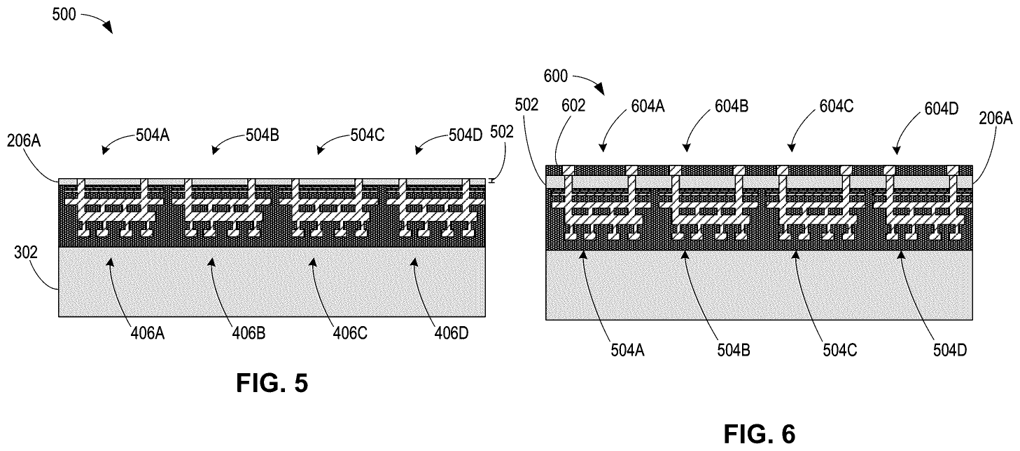

FIG. 5 is a cross-sectional schematic view of an example third intermediate stage 500 of the assembly/manufacturing of the first memory stack 200 of FIG. 2. In some examples, the third intermediate stage 500 occurs after the second intermediate stage 400 of FIG. 4. During the third intermediate stage 500, the wafer 404 is planarized to an example thickness 502 to form the first base 206A of FIG. 2. In the illustrated example of FIG. 2, the planarization of the wafer 404 reveals example first interconnections 504A, example second interconnections 504B, example third interconnections 504C, and example fourth interconnections 504D of the memory dies 406A, 406B, 406C, 406D, respectively. The interconnections 504A, 504B, 504C, 504D are similar to the interconnections 208A, 208B, 208C, 208D, 208E, 208F, 208G, 208H, 208I of FIG. 2. In some examples, the wafer 404 is planarized via chemical mechanical polishing. In other examples, the wafer 404 can be planarized via a different process.

FIG. 6 is a cross-sectional schematic view of an example fourth intermediate stage 600 of the assembly/manufacturing of the first memory stack 200 of FIG. 2. In some examples, the fourth intermediate stage 600 occurs after the third intermediate stage 500 of FIG. 5. During the fourth intermediate stage 600, an example second bonding layer 602 is deposited on the first base 206A. In some examples, the second bonding layer 602 is a surface treatment of the first base 206A (e.g., a fusion layer of silica formed on the silicon, etc.). In some such examples, the second bonding layer 602 is similar to the first bonding layer 304 of FIG. 3. In other examples, the second bonding layer 602 can be formed of any other substance (e.g., a dielectric layer, an adhesive layer, an adhesive film, etc.).

In the illustrated example of FIG. 6, example first pads 604A, example second pads 604B, example third pads 604C, and example fourth pads 604D have been patterned in the second bonding layer 602. In the illustrated example of FIG. 6, the pads 604A, 604B, 604C, 604D are electrically coupled to and abut the interconnections 504A, 504B, 504C, 504D, respectively. The pads 604A, 604B, 604C, 604D enable electrical signals and/or power to be transmitted through the base 206A and the second bonding layer 602 (e.g., between the interconnections 504A, 504B, 504C, 504D, and memory dies deposited on the second bonding layer 602, etc.). In some examples, the pads 604A, 604B, 604C, 604D are patterned via lithography. In other examples, the pads 604A, 604B, 604C, 604D are patterned via a different manufacturing technique. The pads 604A, 604B, 604C, 604D include (e.g., are composed of, etc.) an electrically conductive material (e.g., copper, aluminum, silver, etc.).

FIG. 7 is a cross-sectional schematic view of an example fifth intermediate stage 700 of the assembly/manufacturing of the first memory stack 200 of FIG. 2. In some examples, the fifth intermediate stage 700 occurs after the fourth intermediate stage 600 of FIG. 6. In the intermediate stage 700, an example second wafer assembly 702 is provided. In some examples, the second wafer assembly 702 can be manufactured and/or provided in a similar manner as the first wafer assembly 402 of FIG. 4. In the illustrated example of FIG. 7, the second wafer assembly 702 includes an example wafer 704, which supports an example fifth memory die 706A, an example sixth memory die 706B, an example seventh memory die 706C, and an example eighth memory die 706D. In the illustrated example of FIG. 7, the wafer 704 and the memory dies 706A, 706B, 706C, 706D are similar to the wafer 404 of FIG. 4 and the memory dies 406A, 406B, 406C, 406D of FIG. 4, respectively, except as noted otherwise. In the illustrated example of FIG. 7, the wafer assembly 702 includes an example top surface 708. In the illustrated example of FIG. 7, the memory dies 706A, 706B, 706C, 706D include example fifth interconnections 709A, example sixth interconnections 709B, example seventh interconnections 709C, and example eighth interconnections 709D, which are similar to the interconnections 504A, 504B, 504C, 504D, respectively, except as noted otherwise. The second wafer assembly 702 is to be disposed on (e.g., placed on, bonded to, etc.) on the second bonding layer 602 of FIG. 2 to form a layer of the first memory stack 200 of FIG. 2.

In the illustrated example of FIG. 7, the memory dies 706A, 706B, 706C, 706D of the second wafer assembly 702 have been tested to determine if the memory dies 706A, 706B, 706C, 706D are functional. For example, the memory dies 706A, 706B, 706C, 706D can be tested to determine if the memory dies 706A, 706B, 706C, 706D are able to transmit electrical signals therethrough and able to store memory per the specifications of the memory dies 706A, 706B, 706C, 706D. In some examples, the memory dies 706A, 706B, 706C, 706D can be tested by testing whether signals can be transmitted through the interconnections 709A, 709B, 709C, 709D. In the illustrated example of FIG. 7, the fifth memory die 706A has been determined to be non-functional and is marked with an “X.” In the illustrated example of FIG. 7, an example opening 710 has been formed on the top surface 708 to create an inset surface 712. In the illustrated example of FIG. 7, the opening 710 is aligned with the fifth memory die 706A such that the fifth interconnections 709A are flush with the inset surface 712 and inset for the top surface 708. In some examples, the inset surface 712 IS formed via lithography (e.g., positive lithography, negative lithography, etc.) and/or another suitable semiconductor manufacturing technique. While only one of the memory dies 706A, 706B, 706C, 706D is depicted as non-functional (e.g., the fifth memory die 706A, etc.), in other examples one or more other ones of the memory dies 706A, 706B, 706C, 706D and/or none of the other memory dies 706A, 706B, 706C, 706D can be identified as non-functional. In such examples, inset surface(s) similar to the inset surface 712 can be created and aligned with the identified non-functional ones of the memory dies 706A, 706B, 706C, 706D.

FIG. 8 is a cross-sectional schematic view of an example sixth intermediate stage 800 of the assembly/manufacturing of the first memory stack 200 of FIG. 2. In some examples, the sixth intermediate stage 800 occurs after the fifth intermediate stage 700 of FIG. 7. In the sixth intermediate stage 800, the second wafer assembly 702 of FIG. 7 has been coupled to the first wafer assembly 402 following the intermediate stage 600 of FIG. 6. In the illustrated example of FIG. 8, the second wafer assembly 702 has been flipped and bonded to the second bonding layer 602 of FIG. 6. For example, the top surface 708 of the second wafer assembly 702 can be bonded to the second bonding layer 602 via fusion bonding. In other examples, the second wafer assembly 702 can be coupled to the first wafer assembly 402 via any other suitable bonding technique.

In the illustrated example of FIG. 8, the bonding of the wafer assemblies 402, 702 causes the memory dies 406A, 406B, 406C to be coupled to the memory dies 706B, 706C, 706D (e.g., the first memory die 406A is coupled to the eighth memory die 706D, the second memory die 406B is coupled to the seventh memory die 706C, the third memory die 406C is coupled to the sixth memory die 706B, etc.). That is, in the illustrated example of FIG. 8, the pads 604A, 604B, 604C couple vertically aligned ones of the interconnections 504A, 504B, 504D, 709D, 709C, 709B, which electrically couple corresponding ones of the memory dies 406A, 406B, 406C, 706B, 706C, 706D. In the illustrated example of FIG. 8, the opening 710 causes the inset surface 712 to not be bonded to the first wafer assembly 402. That is, the opening 710 prevents the fifth memory die 706A from being electrically coupled to the pads 604D and the fourth memory die 406D.

FIG. 9 is a cross-sectional schematic view of an example seventh intermediate stage 900 of the assembly/manufacturing of the first memory stack 200 of FIG. 2. In some examples, the seventh intermediate stage 900 occurs after the sixth intermediate stage 800 of FIG. 8. In the intermediate stage 900, an example cut 902 (e.g., a trench, a gap, etc.) is formed in the second wafer assembly 702 and the fifth memory die 706A is removed from the second wafer assembly 702. In some examples, the cut 902 can be formed via plasma dicing and/or lithography. In other examples, the cut 902 can be formed via another suitable method (e.g., mechanical cutting, laser cutting, etc.). In the illustrated example of FIG. 9, the cut 902 extends through the wafer 704 and the eighth memory die 706D to the opening 710, which mechanically uncouples the fifth memory die 706A from the adjacent ones of the memory dies. In some examples, the fifth memory die 706A is mechanically removed from the second wafer assembly 702. It should be appreciated that multiple ones of the memory dies 706A, 706B, 706C, 706D can be similarly removed if identified said ones are identified as non-functional. In some such examples, multiple cuts can be created in the second wafer assembly 702 to remove dies depending on the relative position of the non-functional dies (e.g., multiple cuts could be used to remove the sixth memory die 706B, etc.).

FIG. 10 is a cross-sectional schematic view of an example eighth intermediate stage 1000 of the assembly/manufacturing of the first memory stack 200 of FIG. 2. In some examples, the eighth intermediate stage 1000 occurs after the seventh intermediate stage 900 of FIG. 9. In the intermediate stage 1000 of FIG. 10, the removal of the fifth memory die 706A during the intermediate stage 900 has created an example opening 1002 in the second wafer assembly 702. In some examples, if multiple memory dies were identified as non-functional, the second wafer assembly 702 can include multiple openings similar to the opening 1002 corresponding to the removed memory dies. In the illustrated example of FIG. 10, the removal of the fifth memory die 706A exposes the fourth pads 604D. In some such examples, because the opening 710 of FIG. 7 prevented the fifth memory die 706A from to the fourth pads 604D, the fourth pads 604D have not been previously coupled to a memory die, which prevents the connection fidelity between the fourth pads 604D and a replacement die from being significantly degraded.

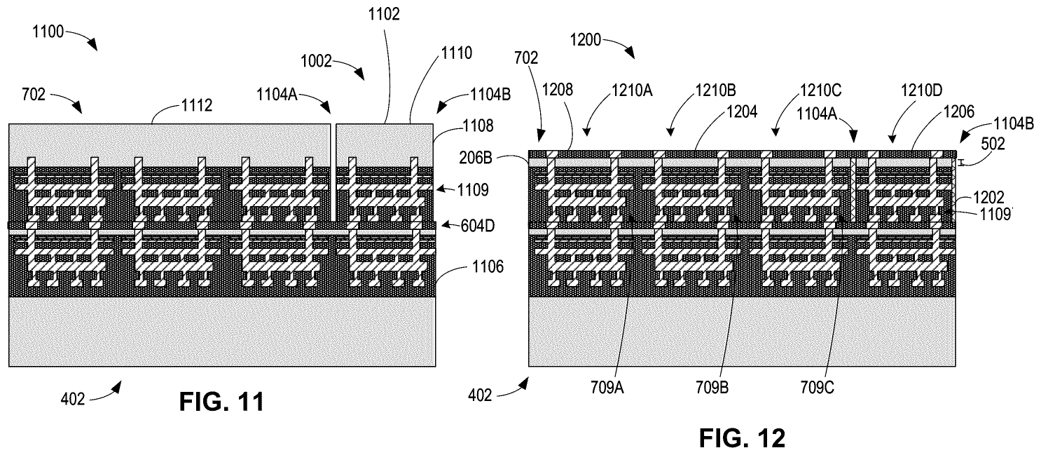

FIG. 11 is a cross-sectional schematic view of an example ninth intermediate stage 1100 of the assembly/manufacturing of the first memory stack 200 of FIG. 2. In some examples, the ninth intermediate stage 1100 occurs after the eighth intermediate stage 1000 of FIG. 10. In the ninth intermediate stage 1100, an example replacement die 1102 has been disposed in the opening 1002. In the illustrated example of FIG. 11, the replacement die 1102 has been fusion bonded to the pads 604D, which forms an electrical connection between the fourth memory die 406D and the replacement die 1102. In the illustrated example of FIG. 11, an example first gap 1104A is formed between the replacement die 1102 and the sixth memory die 706B and an example second gap 1104B is formed between the replacement die 1102 and an example edge 1106 of the wafer assemblies 402, 702. In the illustrated example of FIG. 11, the replacement die 1102 includes an example wafer portion 1108, which includes an example top surface 1110.

The replacement die 1102 is similar to the replacement dies 204A, 204B, 204C of FIG. 2, excepted as noted otherwise. The replacement die 1102 is a known good die (KGD). That is, the replacement die 1102 has been tested and identified as a functional memory die prior to the intermediate stage 1100. In some such examples, the replacement die 1102 is a singulated portion of a wafer assembly similar to the wafer assemblies 402, 702. In some examples, the replacement die 1102 is placed in the opening 1002 via pick and place mounting. In other examples, the replacement die 1102 is disposed in the opening 1002 via any other suitable manufacturing technique. In the illustrated example of FIG. 11, the replacement die 1102 has been bonded to the pads 604D, such that example interconnections 1109 of the replacement die 1102 are electrically coupled to the pads 604D and the fourth memory die 406D of FIG. 4. In the illustrated example of FIG. 11, the first top surface 1110 of the wafer portion 1108 is flush with (e.g., aligned, etc.) with an example second top surface 1112 of the wafer 704. In the illustrated example of FIG. 11, the replacement die 1102 has a smaller width than the fifth memory die 706A, which causes the replacement die 1102 to be spaced from the sixth memory die 706B and the edge 1106 by the gaps 1104A, 1104B, respectively.

FIG. 12 is a cross-sectional schematic view of an example tenth intermediate stage 1200 of the assembly/manufacturing of the first memory stack 200 of FIG. 2. In some examples, the tenth intermediate stage 1200 occurs after the ninth intermediate stage 1100 of FIG. 11. In the tenth intermediate stage 1200, an example dielectric shell 1202 is disposed around the replacement die 1102 of FIG. 2. In the illustrated example of FIG. 12, the second wafer assembly 702 has been planarized to form the second base 206B of FIG. 2. In the illustrated example of FIG. 2, the second base 206B includes an example first base portion 1204 and an example second base portion 1206. In the illustrated example of FIG. 12, an example third bonding layer 1208 has been deposited on the second base 206B. In the illustrated example of FIG. 12, example fifth pads 1210A, example sixth pads 1210B, example seventh pads 1210C, and example eighth pads 1210D have been patterned in the third bonding layer 1208.

In the illustrated example of FIG. 12, the wafer 704 of FIG. 7 and the wafer portion 1108 of FIG. 11 have been planarized to create the first base portion 1204 and the second base portion 1206, respectively. In the illustrated example of FIG. 12, the first base portions 1204 and the second base portion 1206 have the thickness 502 of FIG. 5 (e.g., the same thickness as the first base 206A, etc.). That is, in the illustrated example of FIG. 12, the second base 206B has the same thickness as the first base 206A. In other examples, the second base 206B and the first base 206A can have different thicknesses. In some examples, the wafer 704 of FIG. 7 and the wafer portion 1108 of FIG. 11 are planarized via chemical mechanically planarized. In other examples, the wafer 704 of FIG. 7 and the wafer portion 1108 of FIG. 11 are planarized in any other suitable manner.

In the illustrated example of FIG. 12, the dielectric shell 1202 is a liner that encompasses (e.g., surrounds, etc.) the replacement die 1102. In the illustrated example of FIG. 12, the dielectric shell 1202 has been deposited in the gaps 1104A, 1104B. In some examples, the dielectric shell 1202 is deposited in the gaps 1104A, 1104B as a liquid (e.g., a liquid epoxy, etc.). In some such examples, the dielectric shell 1202 is deposited via inkjetting. In other examples, the dielectric shell 1202 can be deposited in any other suitable manner (e.g., lithography, plating, etc.). In the illustrated example of FIG. 12, the dielectric shell 1202 separates the first base portion 1204 and the second base portion 1206. That is, the dielectric shell 1202 interrupts the second base 206B and separates the replacement die 1102 from the sixth memory die 706B.

In the illustrated example of FIG. 12, the pads 1210A, 1210B, 1210C, 1210D abut and electrically couple the interconnections 709A, 709B, 709C, 1109. In some examples, the third bonding layer 1208 and the pads 1210A, 1210B, 1210C, 1210D are deposited and/or patterned in a similar matter as the second bonding layer 602 of FIG. 6 and the pads 604A, 604B, 604C, 604D of FIG. 6. In other examples, the third bonding layer 1208 and the pads 1210A, 1210B, 1210C, 1210D are deposited and/or patterned in any other suitable manner.

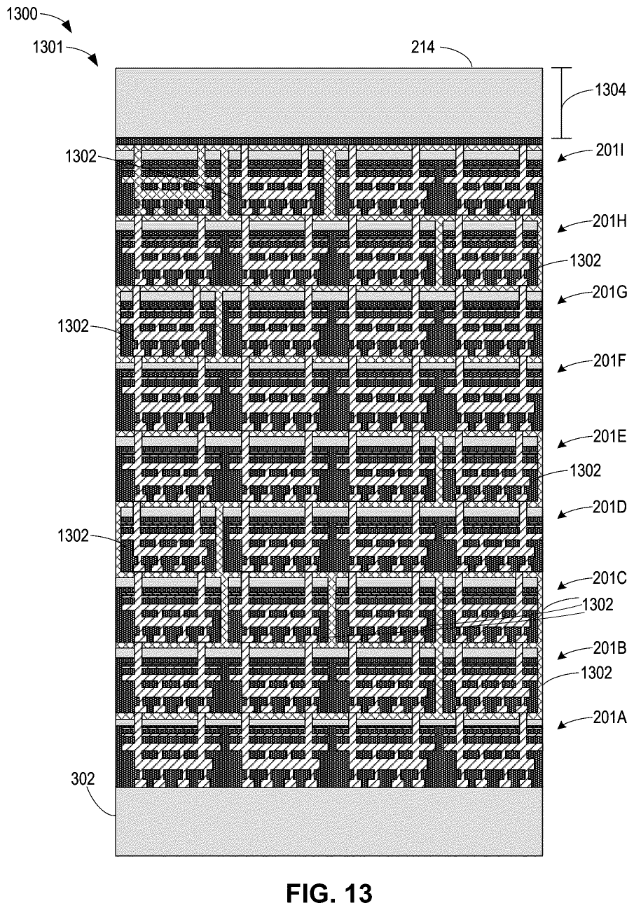

FIG. 13 is a cross-sectional schematic view of an example eleventh intermediate stage 1300 of the assembly/manufacturing of the first memory stack 200 of FIG. 2. In the eleventh intermediate stage 1300, an example wafer-level memory stack assembly 1301 is provided. In some examples, the eleventh intermediate stage 1300 occurs after the repeated iteration of the intermediate stages 700, 800, 900, 1000, 1100, 1200 of FIGS. 7-12. That is, each iteration of the intermediate stages 700, 800, 900, 1000, 1100, 1200 of FIGS. 7-12 creates a layer of the wafer-level memory stack assembly 1301. For example, the wafer-level memory stack assembly 1301 includes the layers 201A, 201B, 201C, 201D, 201E, 201F, 201G, 201H, 201I are subsequently stacked on the carrier 302. In the illustrated example of FIG. 1, the first layer 201A includes the memory dies and base of the first wafer assembly 402 and the second layer 201B includes the memory dies and base of the second wafer assembly 702. In some examples, each of the layers 201C, 201D, 201E, 201F, 201G, 201H, 201I can be manufactured by repeating the intermediate stages 500, 600, 700, 800, 900, 1000, 1100, 1200 of FIGS. 5-12. In the illustrated example of FIG. 13, the wafer-level memory stack assembly 1301 includes example replacement dies 1302. In the illustrated example of FIG. 13, the wafer-level memory stack assembly includes 9 of the replacement dies 1302. It should be appreciated that each of the replacement dies 1302 corresponds to an identified non-functional die that was removed and replaced with a replacement die via the intermediate stages 700, 800, 900, 1000, 1100, 1200.

In the illustrated example of FIG. 13, the example structural lid 214 of FIG. 2 has been disposed on the ninth layer 201I. In the illustrated example of FIG. 13, the structural silicon 214 has an example thickness 1304. In some examples, the thickness 1304 can be based on the desired overall mechanical and/or thermal properties of the wafer-level memory stack assembly 1301 and/or the memory stacks to be singulated from the wafer-level memory stack assembly 1301 (e.g., the first memory stack 200, etc.). In some examples, because the replacement dies 1302 and the associated dielectric shells have different mechanical and thermal properties than the non-replacement dies, the thickness 1304 can be determined based on the quantity of the replacement dies 1302 and/or the distribution of the replacement dies 1302 in the wafer-level memory stack assembly 1301. In some examples, the structural lid 214 is planarized to the desired thickness via mechanical chemical planarization.

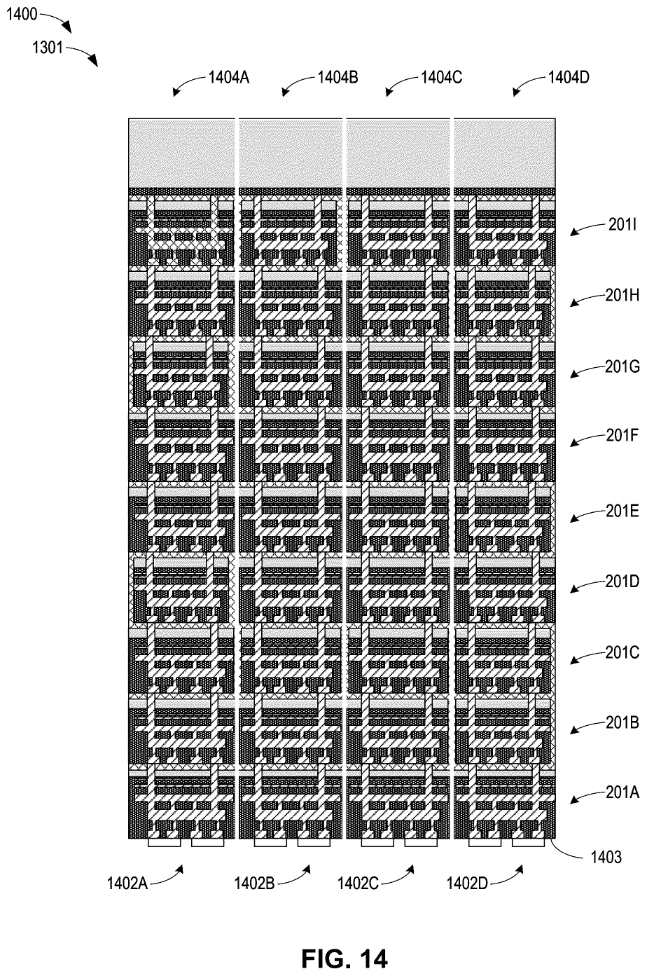

FIG. 14 is a cross-sectional schematic view of an example twelfth intermediate stage 1400 of the assembly/manufacturing of the first memory stack 200 of FIG. 2. In some examples, the twelfth intermediate stage 1400 occurs after the eleventh intermediate stage 1300 of FIG. 13. In the twelfth intermediate stage 1400, the carrier wafer 1302 has been removed from the wafer-level memory stack assembly 1301. In the illustrated example of FIG. 14, example first pads 1402A, example second pads 1402B, example third pads 1402C, and example fourth pads 1402D have been deposited on an example bottom surface 1403 of the first layer 201A (e.g., the location where the carrier 302 was removed from, etc.). In the illustrated example of FIG. 14, the wafer-level memory stack assembly 1301 has been singulated to form an example first memory stack 1404A, an example second memory stack 1404B, an example third memory stack 1404C, and an example fourth memory stack 1404D. In some examples, the first memory stack 200 of FIG. 2 can be implemented by one or more of the memory stacks 1404A, 1404B, 1404C, 1404D. The pads 1402A, 1402B, 1402C, 1402D are similar to the pads 212 and enable the memory stacks 1404A, 1404B, 1404C, 1404D to be mounted on an integrated circuit package 100 of FIG. 1. In some examples, the pads 1402A, 1402B, 1402C, 1402D can be formed via lithography, plating, and/or a similar deposition process.

FIG. 15 is a cross-sectional side view of another example second memory stack 1500 that can implement the memory stack 108 of FIG. 1. In the illustrated example of FIG. 15, the second memory stack 1500 includes the an example first layer 1501A, an example second layer 1501B, an example third layer 1501C, an example fourth layer 1501D, an example fifth layer 1501E, an example sixth layer 1501F, an example seventh layer 1501G, an example eighth layer 1501H, and an example ninth layer 1501I, which are similar to the layers 201A, 201B, 201C, 201D, 201E, 201F, 201G, 201H, 201I of FIG. 2, respectively, except as noted otherwise. In the illustrated example of FIG. 15, the second memory stack 1500 includes the memory dies 202A, 202B, 202C, 202D, 202E, 202F of FIG. 2, the bases 206A, 206B, 206C, 206D, 206E, 206F, 206G, 206H, 206I of FIG. 2, the interconnections 208A, 208C, 208D, 208F, 208G, 208I of FIG. 2, the dielectric shells 210A, 210B, 210C of FIG. 2, the pads 212, and the structural lid 214. The example second memory stack 1500 is similar to the first memory stack 200 of FIG. 2, except that the second memory stack 1500 includes an example first dummy die 1502A, an example second dummy die 1502B, and an example third dummy die 1502C. In the illustrated example of FIG. 15, the dummy dies 1502A, 1502B, 1502C include example first vias 1504A, example second vias 1504B, and example third vias 1504C, respectively.

In the illustrated example of FIG. 15, like the first memory stack 200 of FIG. 2, the second memory stack 1500 includes nine layers (e.g., the layers 1501A, 1501B, 1501C, 1501D, 1501E, 1501F, 1501G, 1501H, 1501I, etc.). In other examples, the first memory stack 200 can include a different quantity of layers. In some examples, the second memory stack 1500 can have a number of layers based on the quantity of dummy dies in the second memory stack 1500. For example, the second memory stack 1500 can include a variable number of layers such that the second memory stack 1500 includes a fixed quantity of functional memory dies. In the illustrated example of FIG. 15, the second memory stack 1500 includes a same quantity of layers (e.g., nine layers, etc.) and dies (e.g., 9 dies, the memory dies 202A, 202B, 202C, 202D, 202E, 202F and the dummy dies 1502A, 1502B, 1502C, etc.) due to the presence of the dummy dies 1502A, 1502B, 1502C. In the illustrated example of FIG. 15, the second memory stack 1500 includes a different quantity of layers (e.g., nine layers, etc.) and memory dies (e.g., 6 memory dies, the memory dies 202A, 202B, 202C, 202D, 202E, 202F, etc.) due to the presence of the dummy dies 1502A, 1502B, 1502C.

In the illustrated example of FIG. 15, the dummy dies 1502A, 1502B, 1502C are disposed in the second layer 1501B, the fifth layer 1501E, and the eighth layer 1501H layer, respectively. The dummy dies 1502A, 1502B, 1502C are similar to the memory dies 202A, 202B, 202C, 202D, 202E, 202F, except that the dummy dies 1502A, 1502B, 1502C are not functional memory modules. That is, the dummy dies 1502A, 1502B, 1502C are semiconductor blocks (e.g., silicon blocks, etc.) that do not include internal structures that enable the dummy dies 1502A, 1502B, 1502C to function as memory modules. The dummy dies 1502A, 1502B, 1502C are also referred to herein as “passthrough dies.” In some examples, the dummy dies 1502A, 1502B, 1502C are composed of a similar material as the body of the memory dies 202A, 202B, 202C, 202D, 202E, 202F (e.g., silicon, etc.). In some such examples, the dummy dies 1502A, 1502B, 1502C have similar mechanical and thermal properties as the memory dies 202A, 202B, 202C, 202D, 202E, 202F. In the illustrated example of FIGS. 15, the dummy dies 1502A, 1502B, 1502C include the vias 1504A, 1504B, 1504C, which enable electrical signals and power to be transmitted therethrough. In some examples, the vias 1504A, 1504B, 1504C are through silicon vias (TSVs).

In the illustrated example of FIG. 15, the dielectric shells 210A, 210B, 210C of FIG. 2 surround (e.g., encompass, line, etc.) the dummy dies 1502A, 1502B, 1502C, respectively. In the illustrated example of FIG. 15, the dummy dies 1502A, 1502B, 1502C have the second width 218 of FIG. 2. In the illustrated example of FIG. 15, the combined width of each of the corresponding pairs of the dummy dies 1502A, 1502B, 1502C and the dielectric shells 210A, 210B, 210C is the first width 216 of FIG. 2. That is, the dielectric shells 210A, 210B, 210C are flush with an example first edge 1506A and an example second edge 1506B of the second memory stack 1500. In the illustrated example of FIG. 15, the dummy dies 1502A, 1502B, 1502C are unitary with the bases 206B, 206E, 206H, respectively. That is, each corresponding pair of the dummy dies 1502A, 1502B, 1502C and the bases 206B, 206E, 206H is a unitary and monolithic whole. In other examples, the dummy dies 1502A, 1502B, 1502C and the bases 206B, 206E, 206H are discrete components that are joined via one or more bonding processes. In some such examples, one or more intermediate layer(s) are disposed between the dummy dies 1502A, 1502B, 1502C and the bases 206B, 206E, 206H, respectively.

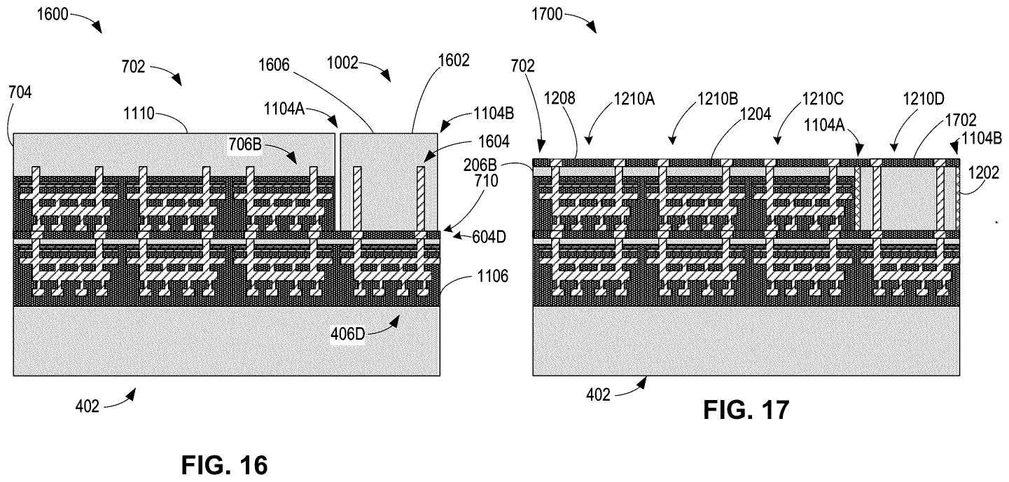

FIGS. 16 and 17 depict two intermediate stages in an example process to manufacture the second memory stack 1500 of FIG. 15. It should be appreciated that other processes can be used to manufacture the second memory stack 1500 of FIG. 15. Example operations to manufacture the second memory stack 1500 of FIG. 15 are described below in conjunction with FIG. 21. In the illustrated examples of FIGS. 16 and 17, the intermediate stages depict wafer-level fabrication to manufacture a row of four memory stacks similar to the second memory stack 1500 of FIG. 15. It should be appreciated that the examples disclosed herein can be used to manufacture a memory stack assembly including any suitable quantity of memory stacks simultaneously (e.g., based on the size of the wafer on which the memory stacks are assembled on, etc.). It should be appreciated that other processes and/or intermediate stages can be used to manufacture the second memory stack 1500 of FIG. 15.

FIG. 16 is a cross-sectional schematic view of an example first intermediate stage 1600 of the assembly/manufacturing of the second memory stack 1500 of FIG. 15. The first intermediate stage 1600 can occur after the eighth intermediate stage 1000 of FIG. 10 (e.g., the removal of a non-functional memory die from a wafer assembly, etc.). In the first intermediate stage 1600, the example first wafer assembly 402 of FIG. 4 has been bonded to the second wafer assembly 702 of FIG. 7 and a non-functional die (e.g., the fifth memory die 706A of FIG. 7, etc.) has been removed. For example, the wafer assemblies 402, 702 can be processed through the intermediate stages 400, 500, 600, 700, 800, 900, 1000 of FIGS. 4-10.

During the first intermediate stage 1600, an example dummy die 1602 has been disposed in the opening 1002 of FIG. 10. In the illustrated example of FIG. 16, the dummy die 1602 has been fusion bonded to the pads 604D of FIG. 16, which forms an electrical connection between the fourth memory die 406D and example vias 1604 of the dummy die 1602. The dummy die 1602 and the vias 1604 are similar to the dummy dies 1502A, 1502B, 1502C and vias 1504A, 1504B, 1504C, respectively, except as noted otherwise. In the illustrated example of FIG. 16, the deposition of the dummy die 1602 on the wafer assemblies 402, 702 creates the first gap 1104A of FIG. 11 between the dummy die 1602 and the sixth memory die 706B and the second gap 1104B of FIG. 11 between the dummy die 1602 and the example edge 1106 of FIG. 11 of the wafer assemblies 402, 702.

In the illustrated example of FIG. 16, the dummy die 1602 includes an example top surface 1606. In some examples, the dummy die 1602 can be a singulated portion of a wafer. In some examples, the dummy die 1602 is placed in the opening 1002 via pick and place mounting. In other examples, the dummy die 1602 is disposed in the opening 1002 via any other suitable manufacturing technique. In the illustrated example of FIG. 16, the dummy die 1602 has been bonded to the pads 604D, such that example vias 1604 of the dummy die 1602 are electrically coupled to the pads 604D and the fourth memory die 406D of FIG. 4. In the illustrated example of FIG. 16, the top surface 1606 of the dummy die 1602 is flush with (e.g., aligned with, etc.) with the top surface 1110 of FIG. 11 of the wafer 704 of FIG. 7. In the illustrated example of FIG. 16, the dummy die 1602 has a smaller width than the replaced memory die (e.g., the fifth memory die 706A, etc.), which causes the dummy die 1602 to be spaced from the sixth memory die 706B and the edge 1106 by the gaps 1104A, 1104B, respectively.

FIG. 17 is a cross-sectional schematic view of an example second intermediate stage 1700 of the assembly/manufacturing of the second memory stack 1500 of FIG. 15. In some examples, the second intermediate stage 1700 occurs after the first intermediate stage 1600 of FIG. 16. At the second intermediate stage 1700, the dielectric shell 1202 of FIG. 12 is disposed around the replacement die 1102 of FIG. 2. The dielectric shell 1202 can be deposited in a manner similar to the process described in conjunction with FIG. 12. In the illustrated example of FIG. 17, the second wafer assembly 702 has been planarized to form the second base 206B of FIG. 2. The second wafer assembly 702 can be planarized in a manner similar to the process described in conjunction with FIG. 12. In the illustrated example of FIG. 17, the second base 206B includes the first base portion 1204 of FIG. 12 and an example second base portion 1702 of FIG. 17.

In the illustrated example of FIG. 17, the third bonding layer 1208 of FIG. 12 has been deposited on the second base 206B. In the illustrated example of FIG. 17, the pads 1210A, 1210B, 1210C, 1210D of FIG. 12 have been patterned in the third bonding layer 1208. The pads 1210A, 1210B, 1210C, 1210D can be patterned in a manner similar to the process described in conjunction with FIG. 12. In the illustrated example of FIG. 17, the dielectric shell 1202 separates the first base portion 1204 and an example second base portion 1702 associated with the dummy die 1602 (e.g., the top of the dummy die 1602, etc.). That is, the dielectric shell 1202 interrupts the first base portion 1204 and separates the dummy die 1602 from the sixth memory die 706B. After the second intermediate stage 1700 of FIG. 17, the fabrication of the second memory stack 1700 can be completed via intermediate stages similar to the intermediate stages 1300, 1400 of FIGS. 13 and 14.

FIG. 18 is a cross-sectional side view of another example memory stack 1800 that can implement the memory stack 108 of FIG. 1. In the illustrated example of FIG. 18, the third memory stack 1800 includes an example first layer 1801A, an example second layer 1801B, an example third layer 1801C, an example fourth layer 1801D, an example fifth layer 1801E, an example sixth layer 1801F, an example seventh layer 1801G, an example eighth layer 1801H, an example ninth layer 1801I, which are similar to the layers 201A, 201B, 201C, 201D, 201E, 201F, 201G, 201H, 201I of FIG. 2, respectively, except as noted otherwise. In the illustrated example of FIG. 18, the third memory stack 1800 includes the memory dies 202A, 202B, 202C, 202D, 202E, 202F of FIG. 2, the bases 206A, 206B, 206C, 206D, 206E, 206F, 206G, 206H, 206I of FIG. 2, the interconnections 208A, 208C, 208D, 208F, 208G, 208I of FIG. 2, the dielectric shells 210A, 210B, 210C of FIG. 2, the pads 212 of FIG. 2, and the structural lid 214 of FIG. 2. The example memory stack 1800 is similar to the first memory stack 200 of FIG. 2, except that the third memory stack 1800 includes an example first dielectric filler 1802A, an example second dielectric filler 1802B, and an example third dielectric filler 1802C. In the illustrated example of FIG. 18, the dielectric filler 1802A, 1802B, 1802C include example first vias 1804A, example second vias 1804B, and example third vias 1804C, respectively.

In the illustrated example of FIG. 18, like the first memory stack 200 of FIG. 2, the third memory stack 1800 includes nine layers (e.g., the layers 1801A, 1801B, 1801C, 1801D, 1801E, 1801F, 1801G, 1801H, 1801I, etc.). In other examples, the third memory stack 1800 can include a different quantity of layers. In some examples, the third memory stack 1800 can have a number of layers based on the quantity of layers that include dielectric fillers in the third memory stack 1800. For example, the third memory stack 1800 can include a variable number of layers such that the third memory stack 1800 includes a fixed quantity of memory dies. In the illustrated example of FIG. 18, the third memory stack 1800 includes a different quantity of layers (e.g., nine layers, etc.) and dies (e.g., 6 dies, the memory dies 202A, 202B, 202C, 202D, 202E, 202F, etc.) due to the presence of the dielectric fillers 1802A, 1802B, 1802C.

In the illustrated example of FIG. 18, the second layer 1801B, the fifth layer 1801E, and the eighth layer 1801H include the first dielectric filler 1802A, the second dielectric filler 1802B, and the third dielectric filler 1802C, respectively. The dielectric fillers 1802A, 1802B, 1802C are not memory modules and are blocks that include (e.g., are composed of, etc.) a non-conductive material (e.g., an epoxy, a polymer, a composite, etc.). The dielectric fillers 1802A, 1802B, 1802C are structural elements that support the memory dies and layers disposed thereon. As used herein, the dielectric fillers 1802A, 1802B, 1802C are also referred to as “dielectric blocks.” In the illustrated example of FIGS. 18, the dielectric fillers 1802A, 1802B, 1802C include the vias 1804A, 1804B, 1804C, which enable electrical signals and power to be transmitted therethrough.

In the illustrated example of FIG. 18, each corresponding pair of the dielectric shells 210A, 210B, 210C and the dielectric fillers 1802A, 1802B, 1802C are unitary (e.g., monolithic, etc.). In some such examples, each corresponding pair of the dielectric fillers 1802A, 1802B, 1802C and the dielectric shells 210A, 210B, 210C are disposed simultaneously on the third memory stack 1800. In some examples, the dielectric shells 210A, 210B, 210C and the dielectric fillers 1802A, 1802B, 1802C are composed of the same material. In other examples, the dielectric shells 210A, 210B, 210C and the dielectric fillers 1802A, 1802B, 1802C are composed of different dielectric materials. In the illustrated example, the dielectric fillers 1802A, 1802B, 1802C surround (e.g., encompass, line, etc.) the dielectric fillers 1802A, 1802B, 1802C, respectively.

In the illustrated example of FIG. 18, the dielectric fillers 1802A, 1802B, 1802C have the second width 218 of FIG. 2. In the illustrated example of FIG. 18, combined width of each of the corresponding pairs of the dielectric fillers 1802A, 1802B, 1802C and the dielectric shells 210A, 210B, 210C is the first width 216. That is, the dielectric shells 210A, 210B, 210C are flush with an example first edge 1806A and an example second edge 1806B of the third memory stack 1800. In the illustrated example of FIG. 18, the dielectric fillers 1802A, 1802B, 1802C are not disposed on corresponding bases (e.g., the bases 206A, 206B, 206C, 206D, 206E, 206F, 206G, 206H, 206I, etc.). In other examples, the dielectric fillers 1802A, 1802B, 1802C are supported by and/or coupled to bases similar to the bases 206A, 206B, 206C, 206D, 206E, 206F, 206G, 206H, 206I. In some such examples, one or more intermediate layer(s) are disposed between the dielectric fillers 1802A, 1802B, 1802C and the corresponding bases.

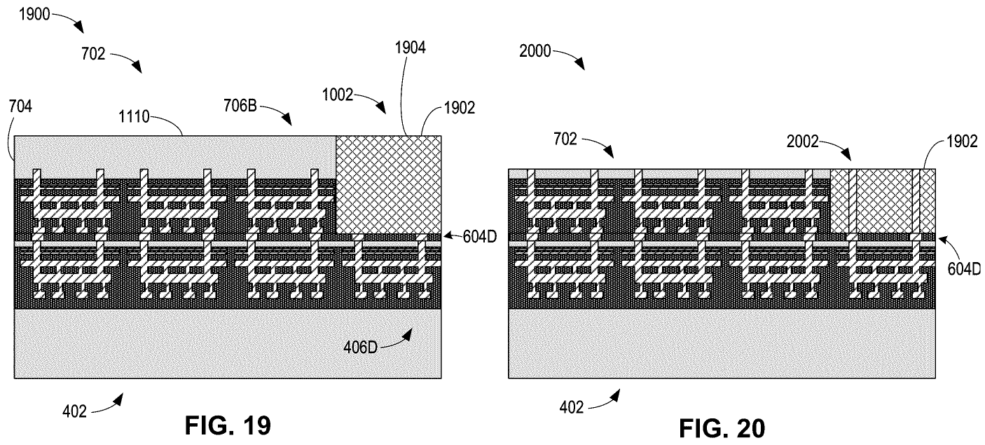

FIGS. 19 and 20 depict two intermediate stages in an example process to manufacture the third memory stack 1800 of FIG. 18. Example operations to manufacture the third memory stack 1800 of FIG. 18 are described below in conjunction with FIG. 21. In the illustrated examples of FIGS. 19 and 20, the intermediate stages depict wafer-level fabrication to manufacture a memory stack assembly including a row of four memory stacks similar to the third memory stack 1800 of FIG. 18. It should be appreciated that the examples disclosed herein can be used to manufacture a memory stack including any suitable quantity of memory stacks simultaneously (e.g., based on the size of the wafer on which the memory stacks are assembled on, etc.). It should be appreciated that other processes and/or intermediate stages can be used to manufacture the third memory stack 1800 of FIG. 18.

FIG. 19 is a cross-sectional schematic view of an example first intermediate stage 1900 of the assembly/manufacturing of the third memory stack 1800 of FIG. 18. The first intermediate stage 1900 can occur after the eighth intermediate stage 1000 of FIG. 10 (e.g., the removal of a non-functional memory die from a wafer assembly, etc.). In the first intermediate stage 1900, the example first wafer assembly 402 of FIG. 4 has been bonded to the second wafer assembly 702 of FIG. 7 and a non-functional die (e.g., the fifth memory die 706A of FIG. 7, etc.) has been removed. For example, the wafer assemblies 402, 702 can be processed through the intermediate stages 400, 500, 600, 700, 800, 900, 1000 of FIGS. 4-10.

At the first intermediate stage 1900, an example dielectric filler 1902 has been disposed in the opening 1002 of FIG. 10. For example, the dielectric filler 1902 can be deposited as a liquid and/or via individual layers via inkjetting, physical vapor deposition, chemical vapor deposition (e.g., atomic layer deposition, etc.), sputtering, and/or another process suitable for deposition of material in the opening 1002. In other examples, the dielectric filler 1902 can be manufactured separately and deposited in the opening 1002 via a pick and place process. In the illustrated example of FIG. 19, the dielectric filler 1902 includes an example top surface 1904. In the illustrated example of FIG. 19, the top surface 1904 is flush with the top surface 1110 of FIG. 11 of the wafer 704 of FIG. 7.

FIG. 20 is a cross-sectional schematic view of an example second intermediate stage 2000 of the assembly/manufacturing of the third memory stack 1800 of FIG. 18. In some examples, the second intermediate stage 2000 occurs after the first intermediate stage 1900 of FIG. 11. In the second intermediate stage 2000 of FIG. 20, example vias 2002 have been formed in the dielectric filler 1902 of FIG. 19 and the dielectric filler 1902 and the wafer 704 have been planarized. In the illustrated example of FIG. 20, the vias 2002 extend through the dielectric filler 1902 to the fourth pads 604D. In some examples, the vias 2002 are created in the dielectric filler 1902 via lithography. In other examples, the vias 2002 can be formed in the dielectric filler 1902 in any other suitable manner. In some examples, the wafer 704 of FIG. 7 and the dielectric filler 1902 of FIG. 19 can be planarized via chemical mechanical planarization. In other examples, the wafer 704 of FIG. 7 and the dielectric filler 1902 of FIG. 11 can be planarized in any other suitable manner. After the second intermediate stage of FIG. 20, the fabrication of the third memory stack 1800 can be completed via intermediate stages similar to the intermediate stages 1200, 1300, 1400 of FIGS. 13-14.

FIGS. 21A and 21B are a block diagram of example operations 2100 for manufacturing a memory stack, such as the first memory stack 200 of FIG. 2, the second memory stack 1500 of FIG. 15, and/or the third memory stack 1800 of FIG. 18. The operations 2100 of FIG. 21 are described with reference to “a replacement block.” As used herein, the term “replacement block” includes replacement memory dies (e.g., the replacement dies 204A, 204B, 204C of FIG. 2, etc.), dummy dies (e.g., the dummy dies 1502A, 1502B, 1502C of FIG. 15, etc.), dielectric fillers (e.g., the dielectric fillers 1802A, 1802B, 1802C of FIG. 18, etc.), and/or any other structure that replaces a non-functional memory die in a memory stack and facilitates the transmission of electrical signals and power therethrough.

The example operations 2100 begin at block 2102, at which the carrier 302 of FIG. 3 is positioned. For example, the carrier 302 can be placed in a fabrication environment. The point of fabrication after completion of block 2102 corresponds to the structure of the first intermediate stage 300 of FIG. 3. At block 2104, the first wafer assembly 402 including a plurality of memory dies is selected. For example, the first wafer assembly 402 of FIG. 4 can be selected. The point of fabrication after completion of block 2102 corresponds to the structure of the first intermediate stage 300 of FIG. 3. At block 2106, the first wafer assembly 402 is bonded to the carrier 302. For example, the first wafer assembly 402 can be fusion bonded to the carrier 302 such that the 406A, 406B, 406C, 406D are coupled to the carrier 302. The point of fabrication after completion of block 2106 corresponds to the structure of the second intermediate stage 400 of FIG. 4.

At block 2108, the first wafer assembly 402 is planarized. For example, the wafer 404 of the first wafer assembly 402 can be planarized to a predetermined thickness (e.g., the thickness 502 of FIG. 5, etc.). In some examples, the remaining portion of the wafer 404 defines the first base 206A of the first layer of the memory stack (e.g., the first layer 201A of the first memory stack 200 of FIG. 2, the first layer 1501A of the second memory stack 1500 of FIG. 15, the first layer 1801A of the third memory stack 1800 of FIG. 18, etc.). In some such examples, the first wafer assembly 402 is planarized via mechanical-chemical planarization. Additionally or alternatively, the first wafer assembly 402 is planarized via a different semiconductor fabrication method. The point of fabrication after completion of block 2108 corresponds to the structure of the third intermediate stage 500 of FIG. 5. At block 2110, the pads 604A, 604B, 604C, 604D of FIG. 6 are patterned on the first wafer assembly 402. For example, the pads 604A, 604B, 604C, 604D on the first wafer assembly 402 can be patterned via lithography. In other examples, the pads 604A, 604B, 604C, 604D are patterned on the first wafer assembly 402 via another suitable semiconductor process. In some examples, the first wafer assembly 402 is treated to form the first bonding layer 602 of FIG. 6 on the first base 206A. Additionally or alternatively, the second bonding layer 602 is deposited on the first base 206A via a material deposition process (e.g., ALD, CVD, PVD, electroplating, etc.). The point of fabrication after completion of block 2110 corresponds to the structure of the fourth intermediate stage 600 of FIG. 6.

At block 2112, another wafer assembly is selected. For example, the second wafer assembly 702 can be selected. In some examples, the wafer assembly selected is the same physical size and includes a same configuration of memory dies as the first wafer assembly 402. In other examples, a wafer assembly of any suitable size or shape is selected. Blocks 2112-2130 of the operations 2100 are described with reference to the second wafer assembly 702 of FIGS. 7-12. It should be appreciated that other wafer assemblies can be processed via the blocks 2112-2130 of the operations 2100.

At block 2114, the memory dies of the second wafer assembly 702 are tested. For example, the memory dies 706A, 706B, 706C, 706D of the second wafer assembly 702 can be tested to determine if one or more of the memory dies 706A, 706B, 706C, 706D are non-functional. After the testing of the memory dies, the non-functional ones of the memory dies (e.g., the fifth memory die 706A in FIG. 7, etc.) are noted (e.g., recorded in a memory of a compute device associated with the fabrication of the memory stack, etc.).

At block 2116, portion(s) of the selected wafer assembly corresponding to the non-functional die(s) are planarized. For example, if the fifth memory die 706A was identified as non-functional during the execution of block 2114, the second wafer assembly 702 can be processed to form the inset surface 712 of FIG. 7, which is inset from the top surface 708 of FIG. 7 of the other dies (e.g., the memory dies 706B, 706C, 706D, etc.) of the second wafer assembly 702. In some examples, the identified portion(s) of the second wafer assembly 702 are planarized via mechanical-chemical planarization. In some examples, the identified portion(s) of the second wafer assembly 702 is planarized via lithography and/or one or more other semiconductor manufacturing processes. The point of fabrication after completion of block 2116 corresponds to the structure of the fifth intermediate stage 700 of FIG. 7.

At block 2118, the selected wafer assembly is bonded to the top wafer assembly of the memory stack. For example, the second wafer assembly 702 can be bonded to the second bonding layer 602 of the first wafer assembly 402. In some examples, the second wafer assembly 702 is fusion bonded to the first wafer assembly 402. In other examples, the second wafer assembly 702 is bonded to the first wafer assembly 402 via another suitable bonding technique (e.g., surface-activated bonding, plasma-activated bonding, anodic bonding, eutectic bonding, adhesive bonding, etc.). In some examples, the bonding of the wafer assemblies 402, 702 electrically couples vertically aligned memory dies of the wafer assemblies 402, 702 (e.g., the eighth memory die 706D to the first memory die 406A, the seventh memory die 706C to the second memory die 406B, the sixth memory die 706B to the third memory die 406C, etc.). In some examples, the planarization of portion(s) of the second wafer assembly 702 corresponding to non-functional dies prevents corresponding connections between vertically aligned memory dies of the wafer assemblies 402, 702 from being created. For example, the opening 710 of FIG. 7 prevents an electrical connection from forming between the fifth memory die 706A and the fourth memory die 406D. The point of fabrication after completion of block 2118 corresponds to the structure of the sixth intermediate stage 800 of FIG. 8.

At block 2120, the non-functional die(s) is/are isolated. For example, the fifth memory die 706A of the second wafer assembly 702 can be isolated from the other memory dies (e.g., the memory dies 706B, 706C, 706D, etc.) of the second wafer assembly 702 (e.g., a trench is formed around the fifth memory die 706A, a gap is formed around the fifth memory die 706A, an opening is formed around the fifth memory die 706A, etc.). In some examples, the fifth memory die 706A is isolated by forming the cut 902. In some examples the cut 902 is formed via plasma cutting. In other examples, the cut 902 is formed via another suitable method (e.g., mechanical cutting, laser cutting, etc.). The point of fabrication after completion of block 2118 corresponds to the structure of the seventh intermediate stage 900 of FIG. 9. At block 2122, the non-functional die(s) of the selected wafer assembly 702 are removed to form corresponding opening(s). For example, the fifth memory die 706A can be removed from the memory stack via a mechanical removal process (e.g., pick and remove, a vacuum removal, gravity removal, etc.). The point of fabrication after completion of block 2118 corresponds to the structure of the eighth intermediate stage 1000 of FIG. 10.

At block 2124, replacement block(s) are placed in the corresponding openings. For example, the replacement die 1102 of FIG. 11 (e.g., a KGD, etc.) can be placed in the opening 1002 and a connection can be formed between the pads 604D and the interconnects 1109 of the replacement die 1102. In some such examples, the point of fabrication after completion of block 2118 corresponds to the structure of the ninth intermediate stage 1100 of FIG. 11 of the first memory stack 200 of FIG. 2. In other examples, the dummy die 1602 of FIG. 16 (e.g., a passthrough die, etc.) can be placed in the opening 1002 and a connection can be formed between the pads 604D and the via 1604 of the dummy die 1602. In some such examples, the point of fabrication after completion of block 2118 corresponds to the structure of the first intermediate stage 1600 of FIG. 16 of the fabrication of the second memory stack 1500 of FIG. 15. In other examples, the dielectric filler 1902 of FIG. 19 (e.g., a dielectric block, etc.) can be placed in the opening 1002 and a connection can be formed between the pads 604D. In some such examples, the vias 2002 of FIG. 20 are patterned in the dielectric filler 1902 (e.g., via lithography, etc.). In some such examples, the point of fabrication after completion of block 2118 corresponds to the structure of the second intermediate stage 2000 of FIG. 20 of the fabrication of the third memory stack 1800 of FIG. 18.

At block 2126, the dielectric shell 1202 is deposited around the replacement block deposited during the execution of block 2124. For example, the dielectric shell 1202 can be deposited in the gaps 1104A, 1104B of FIG. 11. In some such examples, the dielectric shell 1202 is ink jetted into the gaps 1104A, 1104B. In other examples, the dielectric shell 1202 can be deposited into the gaps 1104A, 1104B in any other suitable manner. In some examples, if the dielectric filler 1902 was deposited during the deposition of block 2124, the execution of block 2126 can be omitted.

At block 2128, the selected wafer assembly is planarized. For example, the wafer 704 of the second wafer assembly 702 can be planarized to a predetermined thickness (e.g., the thickness 502 of FIG. 5, etc.). In some examples, the remaining portion of the wafer 704 defines the second base 206B of the first layer of the memory stack (e.g., the second layer 201B of the first memory stack 200 of FIG. 2, the second layer 1501B of the second memory stack 1500 of FIG. 15, the second layer 1801B of the third memory stack 1800 of FIG. 18, etc.). In some such examples, the second wafer assembly 702 is planarized via mechanical-chemical planarization. Additionally or alternatively, the second wafer assembly 702 is planarized via a different semiconductor fabrication method.

At block 2130, pads are patterned on the selected wafer assembly 402. For example, the pads 1210A, 1210B, 1210C, 1210D of FIG. 12 are patterned on the second wafer assembly 702. For example, the pads 1210A, 1210B, 1210C, 1210D on the second wafer assembly 702 can be patterned via lithography. In other examples, the pads 1210A, 1210B, 1210C, 1210D are patterned on the second wafer assembly 702 via another suitable semiconductor process. In some examples, the second wafer assembly 702 is treated to form the third bonding layer 1208 of FIG. 12 on the second base 206B. Additionally or alternatively, the third bonding layer 1208 is deposited on the second base 206B via a material deposition process (e.g., ALD, CVD, PVD, electroplating, etc.). The point of fabrication after completion of block 2130 corresponds to the structure of the tenth intermediate stage 1200 of FIG. 12.

At block 2132, it is determined if another layer is to be placed on the memory stack. For example, the number of layers in the memory stack (e.g., the first memory stack 200 of FIG. 2, the second memory stack 1500 of FIG. 15, the third memory stack 1800 of FIG. 18, etc.) is a predetermined (e.g., fixed, etc.) quantity (e.g., four layers, eight layers, nine layers, sixteen layers, seventeen layers, etc.). In other examples, another layer can be placed on the memory stack until each of the layers includes a predetermined quantity of functional memory dies (e.g., four memory dies, eight memory dies, nine memory dies, sixteen memory dies, seventeen memory dies, etc.). If another layer is to be placed on the memory stack, the operations 2100 return to block 2112. If another layer is not to be placed on the memory stack, the operations advance to block 2133. The point of fabrication after the deposition of each of the layers of the memory stack (e.g., the first memory stack 200, the second memory stack 1500, the third memory stack 1800, etc.) and the completion of block 2132 corresponds to the structure of the eleventh intermediate stage 1300 of FIG. 13. Blocks 2133, 2134, 2136, 2138 of the operations 2100 are further depicted and described in conjunction with FIG. 21B.

At block 2133, the structural lid 214 is deposited on the wafer-level memory stack assembly 1301. For example, the structural lid 214 can be deposited on the uppermost layer of the wafer-level memory stack assembly 1301 via a wafer bonding technique (e.g., fusion bonding, etc.). In some examples, the structural lid 214 can be planarized to a desired thickness (e.g., the thickness 1304, etc.). In some examples, the thickness 1304 of the structural lid 214 can be based on the desired mechanical and/or thermal of the wafer-level memory stack assembly 1301 and/or the memory stacks to be singulated from the wafer-level memory stack assembly 1301 (e.g., the first memory stack 200, etc.). In some examples, because the replacement blocks have different mechanical and thermal properties than the replacement blocks, the thickness 1304 can be determined based on the quantity of the replacement dies 1302 and/or the distribution of the replacement dies 1302 in the wafer-level memory stack assembly 1301.

At block 2134, the carrier 302 is removed from the memory stack. For example, the carrier 302 can be mechanically removed from the wafer-level memory stack assembly 1301, and/or the wafer-level memory stack assembly 1301 can be mechanically removed from the carrier 302. Additionally or alternatively, the carrier 302 is removed via planarization. At block 2136, the pads 1402A, 1402B, 1402C, 1402D are patterned on the bottom of the first wafer assembly 402. For example, the pads 1402A, 1402B, 1402C, 1402D can be patterned via lithography. In other examples, the pads 1402A, 1402B, 1402C, 1402D can be patterned via any other suitable semiconductor manufacturing process. The point of fabrication after completion of block 2136 corresponds to the structure of the twelfth intermediate stage 1400 of FIG. 14. At block 2138, the wafer-level memory stack assembly 1301 is singulated to form a plurality of memory stacks. For example, the wafer-level memory stack assembly 1301 can be singulated via one or more cutting processes (e.g., laser cutting, plasma cutting, mechanical cutting, etc.). The point of fabrication after completion of block 2138 corresponds to the structure of the twelfth intermediate stage 1400 of FIG. 14. After the singulation of the wafer-level memory stack assembly 1301, the individual memory stacks formed therefrom can be mounted to the package substrate of an integrated circuit package, such as the integrated circuit package 100 of FIG. 1. The operations 2100 end.

Although the example operations 2100 are described with reference to the flowchart illustrated in FIG. 21, many other methods of assembling/manufacturing the first memory stack 200 of FIG. 2, the second memory stack 1500 of FIG. 15, and/or the third memory stack 1800 of FIG. 18 may alternatively be used. For example, the order of execution of the blocks may be changed, and/or some of the blocks described may be changed, eliminated, or combined.

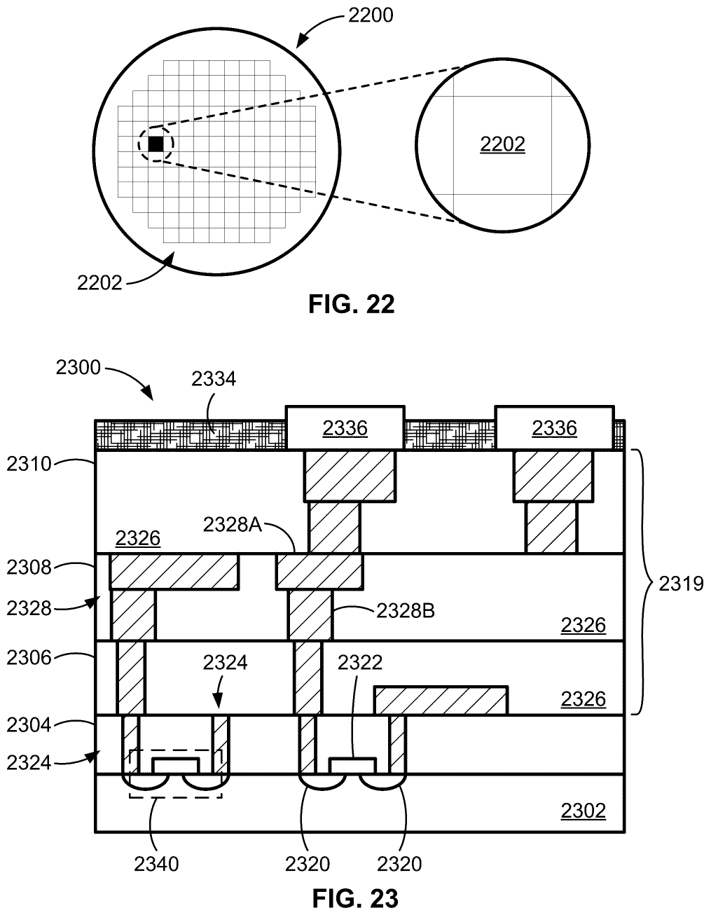

FIG. 22 is a top view of an example wafer 2200 and dies 2202 that may be included in the IC package 100 (e.g., as any suitable ones of the die 106, the memory stack 108, etc.). The wafer 2200 may be composed of semiconductor material and may include one or more dies 2202 having circuitry. Some or all of the dies 2202 may be a repeating unit of a semiconductor product. After the fabrication of the semiconductor product is complete, the wafer 2200 may undergo a singulation process in which the dies 2202 are separated from one another to provide discrete “chips.” One or more of the dies 2202 may include one or more transistors (e.g., some of the transistors 2340 of FIG. 23, discussed below), supporting circuitry to route electrical signals to the transistors, passive components (e.g., traces, resistors, capacitors, inductors, and/or other circuitry), and/or any other components. In some examples, the dies 2202 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die (e.g., a die of the dies 2202 of FIG. 22, etc.). For example, a memory array formed by multiple memory circuits may be formed on a same die (e.g., one of the dies 2202 of FIG. 22, etc.) as programmable circuitry or other logic circuitry. Such memory may store information for use by the programmable circuitry. The example IC package 100 disclosed herein may be manufactured using a die-to-wafer assembly technique in which the die 106, the memory stack 108, etc. are attached to a wafer 2200 that include others of the die 106, the memory stack 108, and the wafer 2200 is subsequently singulated.

FIG. 23 is a cross-sectional side view of an example IC device 2300 that may be included in the example IC package 100 (e.g., in any one of the die 106, the memory stack 108, etc.). One or more of the IC devices 2300 may be included in one or more dies 2202 (FIG. 22). The IC device 2300 may be formed on an example die substrate 2302 (e.g., the wafer 2200 of FIG. 22) and may be included in a die (e.g., a die of the dies 2202 of FIG. 22). The die substrate 2302 may be a semiconductor substrate composed of semiconductor material systems including, for example, n-type or p-type materials systems (or a combination of both). The die substrate 2302 may include, for example, a crystalline substrate formed using a bulk silicon or a silicon-on-insulator (SOI) substructure. In some examples, the die substrate 2302 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 2302. Although a few examples of materials from which the die substrate 2302 may be formed are described here, any material that may serve as a foundation for an IC device 2300 may be used. The die substrate 2302 may be part of a singulated die (e.g., the dies 2202 of FIG. 22) or a wafer (e.g., the wafer 2200 of FIG. 22).

The IC device 2300 may include one or more example device layers 2304 disposed on or above the die substrate 2302. The device layer 2304 may include features of one or more example transistors 2340 (e.g., metal oxide semiconductor field-effect transistors (MOSFETs)) formed on the die substrate 2302. The device layer 2304 may include, for example, one or more example source and/or drain (S/D) regions 2320, an example gate 2322 to control current flow between the S/D regions 2320, and one or more example S/D contacts 2324 to route electrical signals to/from the S/D regions 2320. The transistors 2340 may include additional features not depicted for the sake of clarity such as, for example, device isolation regions, gate contacts, and the like. The transistors 2340 are not limited to the type and configuration depicted in FIG. 23 and may include a wide variety of other types and/or configurations such as, for example, planar transistors, non-planar transistors, or a combination of both. Non-planar transistors may include FinFET transistors such as for example, double-gate transistors, tri-gate transistors, wrap-around gate transistor, and/or all-around gate transistors, such as nanoribbon and/or nanowire transistors.

Some or all of the transistors 2340 may include an example gate 2322 formed of at least two layers including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 2340 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included for other purposes, such as, for example, a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 2340 along the source-channel-drain direction, the gate electrode may include a U-shaped structure that includes a bottom portion substantially parallel to the surface of the die substrate 2302 and two sidewall portions that are substantially perpendicular to the top surface of the die substrate 2302. In other examples, at least one of the metal layers that form the gate electrode may be a planar layer that is substantially parallel to the top surface of the die substrate 2302 and does not include sidewall portions substantially perpendicular to the top surface of the die substrate 2302. In other examples, the gate electrode may include a combination of U-shaped structures and planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers include deposition and etching process steps. In some examples, a plurality of spacer pairs may be used; for instance, two pairs, three pairs, or four pairs of sidewall spacers may be formed on opposing sides of the gate stack.

The S/D regions 2320 may be formed within the die substrate 2302 adjacent to the gate 2322 of respective ones of the transistors 2340. The S/D regions 2320 may be formed using an implantation/diffusion process or an etching/deposition process, for example. In the former process, dopants such as boron, aluminum, antimony, phosphorous, or arsenic may be ion-implanted into the die substrate 2302 to form the S/D regions 2320. An annealing process that activates the dopants and causes the dopants to diffuse farther into the die substrate 2302 may follow the ion-implantation process. In the latter process, the die substrate 2302 may first be etched to form recesses at the locations of the S/D regions 2320. An epitaxial deposition process may then be carried out to fill the recesses with material that is used to fabricate the S/D regions 2320. In some implementations, the S/D regions 2320 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 2320 may be formed using one or more alternate semiconductor materials such as germanium or a group III-V material or alloy. In further examples, one or more layers of metal and/or metal alloys may be used to form the S/D regions 2320.

Electrical signals, such as power and/or input/output (I/O) signals, may be routed to and/or from the devices (e.g., transistors 2340) of the device layer 2304 through one or more example interconnect layers disposed on the device layer 2304 (illustrated in FIG. 23 as interconnect layers 2306-2310). For example, electrically conductive features of the device layer 2304 (e.g., the gate 2322 and the S/D contacts 2324) may be electrically coupled with example interconnect structures 2328 of the interconnect layers 2306-2310. The one or more interconnect layers 2306-2310 may form an example metallization stack (also referred to as an “ILD stack”) 2319 of the IC device 2300.

The interconnect structures 2328 may be arranged within the interconnect layers 2306-2310 to route electrical signals according to a wide variety of designs (in particular, the arrangement is not limited to the particular configuration of interconnect structures 2328 depicted in FIG. 23). Although a particular number of interconnect layers 2306-2310 is depicted in FIG. 23, examples of the present disclosure include IC devices having more or fewer interconnect layers than depicted.

In some examples, the interconnect structures 2328 may include example lines 2328A and/or example vias 2328B filled with an electrically conductive material such as a metal. The lines 2328A may be arranged to route electrical signals in a direction of a plane that is substantially parallel with a surface of the die substrate 2302 upon which the device layer 2304 is formed. For example, the lines 2328A may route electrical signals in a direction in and out of the page from the perspective of FIG. 23. The vias 2328B may be arranged to route electrical signals in a direction of a plane that is substantially perpendicular to the surface of the die substrate 2302 upon which the device layer 2304 is formed. In some examples, the vias 2328B may electrically couple lines 2328A of different interconnect layers 2306-2310 together.

The interconnect layers 2306-2310 may include an example dielectric material 2326 disposed between the interconnect structures 2328, as shown in FIG. 23. In some examples, the dielectric material 2326 disposed between the interconnect structures 2328 in different ones of the interconnect layers 2306-2310 may have different compositions. In other examples, the composition of the dielectric material 2326 between different interconnect layers 2306-2310 may be the same.

A first interconnect layer 2306 (referred to as Metal 1 or “M1”) may be formed directly on the device layer 2304. In some examples, the first interconnect layer 2306 may include lines 2328A and/or vias 2328B, as shown. The lines 2328A of the first interconnect layer 2306 may be coupled with contacts (e.g., the S/D contacts 2324) of the device layer 2304.

A second interconnect layer 2308 (referred to as Metal 2 or “M2”) may be formed directly on the first interconnect layer 2306. In some examples, the second interconnect layer 2308 may include vias 2328B to couple the lines 2328A of the second interconnect layer 2308 with the lines 2328A of the first interconnect layer 2306. Although the lines 2328A and the vias 2328B are structurally delineated with a line within each interconnect layer (e.g., within the second interconnect layer 2308) for the sake of clarity, the lines 2328A and the vias 2328B may be structurally and/or materially contiguous (e.g., simultaneously filled during a dual-damascene process) in some examples.

A third interconnect layer 2310 (referred to as Metal 3 or “M3”) (and additional interconnect layers, as desired) may be formed in succession on the second interconnect layer 2308 according to similar techniques and configurations described in connection with the second interconnect layer 2308 and/or the first interconnect layer 2306. In some examples, the interconnect layers that are “higher up” in the metallization stack 2319 in the IC device 2300 (i.e., further away from the device layer 2304) may be thicker.

The IC device 2300 may include an example solder resist material 2334 (e.g., polyimide or similar material) and one or more example conductive contacts 2336 formed on the interconnect layers 2306-2310. In FIG. 23, the conductive contacts 2336 are illustrated as taking the form of bond pads. The conductive contacts 2336 may be electrically coupled with the interconnect structures 2328 and configured to route the electrical signals of the transistor(s) 2340 to other external devices. For example, solder bonds may be formed on the one or more conductive contacts 2336 to mechanically and/or electrically couple a chip including the IC device 2300 with another component (e.g., a circuit board). The IC device 2300 may include additional or alternate structures to route the electrical signals from the interconnect layers 2306-2310; for example, the conductive contacts 2336 may include other analogous features (e.g., posts) that route the electrical signals to external components.

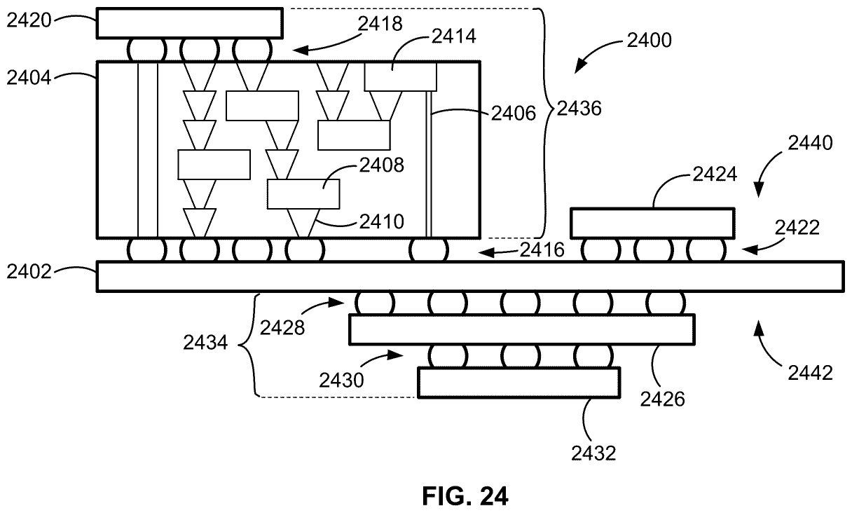

FIG. 24 is a cross-sectional side view of an example IC device assembly 2400 that may include the IC package 100 disclosed herein. In some examples, the IC device assembly corresponds to the IC package 100. The IC device assembly 2400 includes a number of components disposed on an example circuit board 2402 (which may be, for example, a motherboard). The IC device assembly 2400 includes components disposed on an example first face 2440 of the circuit board 2402 and an example opposing second face 2442 of the circuit board 2402. Any of the IC packages discussed herein with reference to the IC device assembly 2400 may take the form of the example IC package 100.

In some examples, the circuit board 2402 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2402. In other examples, the circuit board 2402 may be a non-PCB substrate. In some examples, the circuit board 2402 may be, for example, the circuit board 102 of FIG. 1.

The IC device assembly 2400 illustrated in FIG. 24 includes an example package-on-interposer structure 2436 coupled to the first face 2440 of the circuit board 2402 by example coupling components 2416. The coupling components 2416 may electrically and mechanically couple the package-on-interposer structure 2436 to the circuit board 2402, and may include solder balls (as shown in FIG. 24), male and female portions of a socket, an adhesive, an underfill material, and/or any other suitable electrical, chemical, and/or mechanical coupling structure.

The package-on-interposer structure 2436 may include an example IC package 2420 coupled to an example interposer 2404 by example coupling components 2418. The coupling components 2418 may take any suitable form for the application, such as the forms discussed above with reference to the coupling components 2416. Although a single IC package 2420 is shown in FIG. 24, multiple IC packages may be coupled to the interposer 2404. Additionally or alternatively, in some examples, additional interposers may be coupled to the interposer 2404. The interposer 2404 may provide an intervening substrate used to bridge the circuit board 2402 and the IC package 2420. The IC package 2420 may be or include, for example, a die (e.g., a die of the dies 2202 of the dies of FIG. 22), an IC device (e.g., the IC device 2300 of FIG. 23), and/or any other suitable component(s). Generally, the interposer 2404 may spread a connection to a wider pitch or reroute a connection to a different connection. For example, the interposer 2404 may couple the IC package 2420 (e.g., a die) to a set of BGA conductive contacts of the coupling components 2416 for coupling to the circuit board 2402. In the example illustrated in FIG. 24, the IC package 2420 and the circuit board 2402 are attached to opposing sides of the interposer 2404. In other examples, the IC package 2420 and the circuit board 2402 may be attached to a same side of the interposer 2404. In some examples, three or more components may be interconnected by way of the interposer 2404.

In some examples, the interposer 2404 may be formed as a PCB, including multiple metal layers separated from one another by layers of dielectric material and interconnected by electrically conductive vias. In some examples, the interposer 2404 may be formed of an epoxy resin, a fiberglass-reinforced epoxy resin, an epoxy resin with inorganic fillers, a ceramic material, or a polymer material such as polyimide. In some examples, the interposer 2404 may be formed of alternate rigid or flexible materials that may include the same materials described above for use in a semiconductor substrate, such as silicon, germanium, and other group III-V and group IV materials. The interposer 2404 may include example metal interconnects 2408 and example vias 2410, including but not limited to example through-silicon vias (TSVs) 2406. The interposer 2404 may further include example embedded devices 2414, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2404. The package-on-interposer structure 2436 may take the form of any of the package-on-interposer structures known in the art.

The IC device assembly 2400 may include an example IC package 2424 coupled to the first face 2440 of the circuit board 2402 by example coupling components 2422. The coupling components 2422 may take the form of any of the examples discussed above with reference to the coupling components 2416, and the IC package 2424 may take the form of any of the examples discussed above with reference to the IC package 2420.

The IC device assembly 2400 illustrated in FIG. 24 includes an example package-on-package structure 2434 coupled to the second face 2442 of the circuit board 2402 by coupling components 2428. The package-on-package structure 2434 may include a first example IC package 2426 and a second example IC package 2432 coupled together by example coupling components 2430 such that the first IC package 2426 is disposed between the circuit board 2402 and the second IC package 2432. The coupling components 2428, 2430 may take the form of any of the examples of the coupling components 2416 discussed above, and the IC packages 2426, 2432 may take the form of any of the examples of the IC package 2420 discussed above.

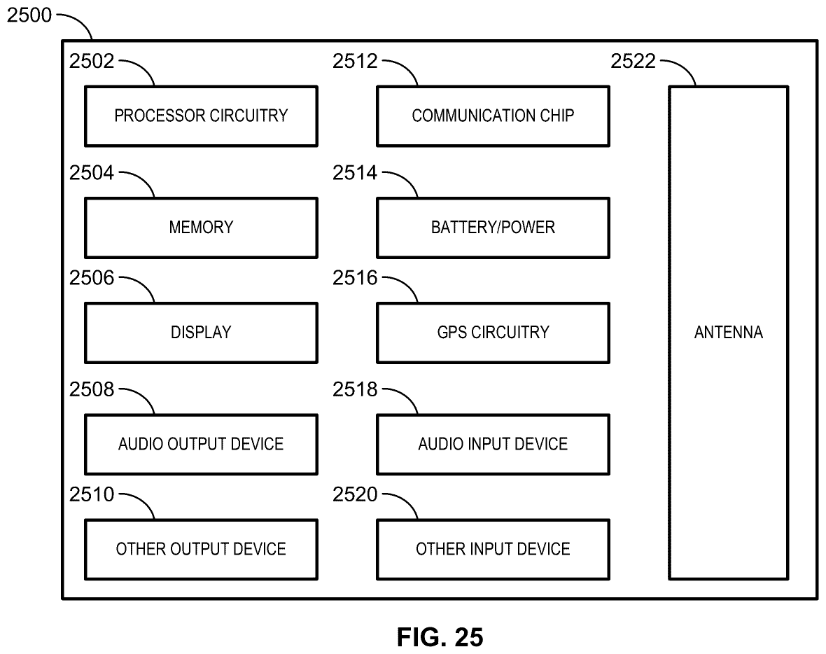

FIG. 25 is a block diagram of an example electrical device 2500 that may include one or more of the example IC package 100. For example, any suitable ones of the components of the electrical device 2500 may include one or more of the device assemblies 2400, IC devices 2300, or dies 2202 disclosed herein, and may be arranged in the example IC package 100. A number of components are illustrated in FIG. 25 as included in the electrical device 2500, but any one or more of these components may be omitted or duplicated, as suitable for the application. In some examples, some or all of the components included in the electrical device 2500 may be attached to one or more motherboards. In some examples, some or all of these components are fabricated onto a single system-on-a-chip (SoC) die.

Additionally, in some examples, the electrical device 2500 may not include one or more of the components illustrated in FIG. 25, but the electrical device 2500 may include interface circuitry for coupling to the one or more components. For example, the electrical device 2500 may not include an example display 2506, but may include display interface circuitry (e.g., a connector and driver circuitry) to which the display 2506 may be coupled. In some examples, the electrical device 2500 may not include an example audio input device 2518 (e.g., microphone) or an example audio output device 2508 (e.g., a speaker, a headset, earbuds, etc.), but may include audio input or output device interface circuitry (e.g., connectors and supporting circuitry) to which the audio input device 2518 or the audio output device 2508 may be coupled.

The electrical device 2500 may include example programmable or processor circuitry 2502 (e.g., one or more processing devices). The processor circuitry 2502 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The electrical device 2500 may include an example memory 2504, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 2504 may include memory that shares a die with the processor circuitry 2502. This memory may be used as cache memory and may include embedded dynamic random access memory (eDRAM) or spin transfer torque magnetic random access memory (STT-MRAM).

In some examples, the electrical device 2500 may include an example communication chip 2512 (e.g., one or more communication chips). For example, the communication chip 2512 may be configured for managing wireless communications for the transfer of data to and from the electrical device 2500. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 2512 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2512 may operate in accordance with other wireless protocols in other examples. The electrical device 2500 may include an example antenna 2522 to facilitate wireless communications and/or to receive other wireless communications (such as AM or FM radio transmissions).

In some examples, the communication chip 2512 may manage wired communications, such as electrical, optical, or any other suitable communication protocols (e.g., the Ethernet). As noted above, the communication chip 2512 may include multiple communication chips. For instance, a first communication chip 2512 may be dedicated to shorter-range wireless communications such as Wi-Fi or Bluetooth, and a second communication chip 2512 may be dedicated to longer-range wireless communications such as global positioning system (GPS), EDGE, GPRS, CDMA, WiMAX, LTE, EV-DO, or others. In some examples, a first communication chip 2512 may be dedicated to wireless communications, and a second communication chip 2512 may be dedicated to wired communications.

The electrical device 2500 may include example battery/power circuitry 2514. The battery/power circuitry 2514 may include one or more energy storage devices (e.g., batteries or capacitors) and/or circuitry for coupling components of the electrical device 2500 to an energy source separate from the electrical device 2500 (e.g., AC line power).

The electrical device 2500 may include the display 2506 (or corresponding interface circuitry, as discussed above). The display 2506 may include any visual indicators, such as a heads-up display, a computer monitor, a projector, a touchscreen display, a liquid crystal display (LCD), a light-emitting diode display, or a flat panel display.

The electrical device 2500 may include the audio output device 2508 (or corresponding interface circuitry, as discussed above). The audio output device 2508 may include any device that generates an audible indicator, such as speakers, headsets, or earbuds.

The electrical device 2500 may include the audio input device 2518 (or corresponding interface circuitry, as discussed above). The audio input device 2518 may include any device that generates a signal representative of a sound, such as microphones, microphone arrays, or digital instruments (e.g., instruments having a musical instrument digital interface (MIDI) output).

The electrical device 2500 may include example GPS circuitry 2516. The GPS circuitry 2516 may be in communication with a satellite-based system and may receive a location of the electrical device 2500, as known in the art.

The electrical device 2500 may include any other example output device 2510 (or corresponding interface circuitry, as discussed above). Examples of the other output device 2510 may include an audio codec, a video codec, a printer, a wired or wireless transmitter for providing information to other devices, and/or an additional storage device.

The electrical device 2500 may include any other example input device 2520 (or corresponding interface circuitry, as discussed above). Examples of the other input device 2520 may include an accelerometer, a gyroscope, a compass, an image capture device, a keyboard, a cursor control device such as a mouse, a stylus, a touchpad, a bar code reader, a Quick Response (QR) code reader, any sensor, and/or a radio frequency identification (RFID) reader.

The electrical device 2500 may have any desired form factor, such as, for example, a hand-held or mobile electrical device (e.g., a cell phone, a smart phone, a mobile internet device, a music player, a tablet computer, a laptop computer, a netbook computer, an ultrabook computer, a personal digital assistant (PDA), an ultra-mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device (e.g., a smartwatch, a ring, googles, a headset, glasses, etc.). In some examples, the electrical device 2500 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

Memory stacks including replacement blocks and related methods are disclosed herein. Further examples and combinations thereof include the following:

Example 1 includes an integrated circuit comprising a first layer including a memory die, and a second layer including a replacement block communicatively coupled to the memory die, the second layer including and a dielectric shell surrounding the replacement block.

Example 2 includes the integrated circuit of example 1, wherein the replacement block is a dummy die.

Example 3 includes the integrated circuit of example 1, wherein the memory die is a first memory die, and the replacement block is a second memory die.

Example 4 includes the integrated circuit of example 1, wherein the replacement block includes a dielectric filler and a via.

Example 5 includes the integrated circuit of any one of examples 1-4, further including at least eight memory layers including the first layer and the second layer.

Example 6 includes the integrated circuit of any one of examples 1-4, wherein the first layer includes a base that includes a first edge, the dielectric shell includes a second edge, and the first edge and the second edge are substantially flush.

Example 7 includes the integrated circuit of any one of examples 1-4, wherein the memory die has a first width, is less than the replacement block has a second width less than the first width.

Example 8 includes an integrated circuit package comprising a substrate, and a memory stack coupled to the substrate, the memory stack including a first memory layer including a memory die, and a second memory layer including a replacement block, and a dielectric shell extending over the replacement block.

Example 9 includes the integrated circuit package of example 8, wherein the replacement block is a dummy silicon die.

Example 10 includes the integrated circuit package of example 8, wherein the memory die is a first memory die and the replacement block includes a second memory die.

Example 11 includes the integrated circuit package of example 8, wherein the replacement block includes a dielectric block and an interconnect.

Example 12 includes the integrated circuit package of any one of examples 8-11, wherein the memory die has a first width, is less than the replacement block has a second width less than the first width.

Example 13 includes the integrated circuit package of any one of examples 8-11, wherein the second layer includes a base disposed above the replacement block.

Example 14 includes the integrated circuit package of example 13, wherein the dielectric shell extends over the base.

Example 15 includes an integrated circuit package comprising a substrate, and a memory stack carried by the substrate, the memory stack including a memory die, and a dummy die vertically aligned with the memory die.

Example 16 includes the integrated circuit package of example 15, wherein the memory die is a first memory die, the memory stack further includes a second memory die, and the dummy die includes an interconnect electrically coupling the first memory die and the second memory die.

Example 17 includes the integrated circuit package of example 15, wherein the memory stack includes a dielectric shell surrounding the dummy die.

Example 18 includes the integrated circuit package of example 15, wherein the dummy die includes a silicon block.

Example 19 includes the integrated circuit package of any one of examples 15-18, wherein the memory die has a first width, is less than the dummy die has a second width less than the first width.

Example 20 includes the integrated circuit package of any one of examples 15-18, wherein the memory stack includes a first quantity of memory layers and a second quantity of dummy dies including the dummy die, wherein the first quantity is based on the second quantity.

Example 21 includes a method comprising identifying a memory die of a wafer as defective, patterning the wafer to generate a memory layer, creating an opening in the memory layer by removing the memory die, and depositing a replacement block in the opening.

Example 22 includes the method of example 21, wherein the memory die is a first die and depositing the replacement block includes depositing a second die in the opening.

Example 23 includes the method of example 21, wherein depositing the replacement block includes depositing a dielectric material into the opening, and forming a via in the dielectric material.

Example 24 includes the method of any one of examples 21-23, further including planarizing a portion of the wafer corresponding to the memory die.

Example 25 includes the method of example 24, wherein the creating of the opening in the memory layer includes creating a trench around the memory die, and mechanically removing the memory die.

Example 26 includes the method of example 24, further including depositing at least six memory layers on the memory layer.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An integrated circuit comprising:
a first layer including a memory die; and
a second layer including:
a replacement block communicatively coupled to the memory die; and
a dielectric shell surrounding the replacement block.

2. The integrated circuit of claim 1, wherein the replacement block is a dummy die.

3. The integrated circuit of claim 1, wherein the memory die is a first memory die, and the replacement block is a second memory die.

4. The integrated circuit of claim 1, wherein the replacement block includes a dielectric filler and a via.

5. The integrated circuit of claim 1, further including at least eight memory layers including the first layer and the second layer.

6. The integrated circuit of claim 1, wherein the first layer includes a base that includes a first edge, the dielectric shell includes a second edge, and the first edge and the second edge are substantially flush.

7. The integrated circuit of claim 1, wherein the memory die has a first width, is less than the replacement block has a second width less than the first width.

8. An integrated circuit package comprising:
a substrate; and
a memory stack coupled to the substrate, the memory stack including:
a first memory layer including a memory die; and
a second memory layer including:
a replacement block; and
a dielectric shell extending over the replacement block.

9. The integrated circuit package of claim 8, wherein the replacement block is a dummy silicon die.

10. The integrated circuit package of claim 8, wherein the memory die is a first memory die and the replacement block includes a second memory die.

11. The integrated circuit package of claim 8, wherein the replacement block includes a dielectric block and an interconnect.

12. The integrated circuit package of claim 8, wherein the memory die has a first width, is less than the replacement block has a second width less than the first width.

13. The integrated circuit package of claim 8, wherein the second memory layer includes a base disposed above the replacement block.

14. The integrated circuit package of claim 13, wherein the dielectric shell extends over the base.

15. An integrated circuit package comprising:
a substrate; and
a memory stack carried by the substrate, the memory stack including:
a memory die; and
a dummy die vertically aligned with the memory die.

16. The integrated circuit package of claim 15, wherein the memory die is a first memory die, the memory stack further includes a second memory die, and the dummy die includes an interconnect electrically coupling the first memory die and the second memory die.

17. The integrated circuit package of claim 15, wherein the memory stack includes a dielectric shell surrounding the dummy die.

18. The integrated circuit package of claim 15, wherein the dummy die includes a silicon block.

19. The integrated circuit package of claim 15, wherein the memory die has a first width, is less than the dummy die has a second width less than the first width.

20. The integrated circuit package of claim 15, wherein the memory stack includes a first quantity of memory layers and a second quantity of dummy dies including the dummy die, wherein the first quantity is based on the second quantity.
